(19) United States
(12) Patent Application Publication
(10) Pub. No.: US 2026/0314183 A1
(43) Pub. Date: Oct. 8, 2026

(54) DISPLAY DEVICE, ELECTRONIC DEVICE USING THE DISPLAY DEVICE, AND METHOD FOR FABRICATING THE DISPLAY DEVICE

(71) Applicant: Samsung Display Co., Ltd., Yongin-si (KR)

(72) Inventors: Chang Suk LEE, Yongin-si (KR); Tae Sung KIM, Yongin-si (KR); Dae Won CHOI, Yongin-si (KR)

(21) Appl. No.: 19/449,840

(22) Filed: Jan. 15, 2026

(30) Foreign Application Priority Data
Apr. 3, 2025 (KR) 10-2025-0043196

(51) Int. Cl. H10K 59/122; H10K 50/11; H10K 59/12

(52) U.S. Cl. CPC H10K 59/122; H10K 50/11; H10K 59/1201

(57) ABSTRACT

There is provided a display device. The display device includes a substrate comprising including a light emission area and a non-light emission area; a bank structure positioned on the light emission area of the substrate and having an overhang structure; an anode electrode positioned on the bank structure; and an element insulating layer positioned between the bank structure and the anode electrode. The element insulating layer includes a flat portion overlapping the light emission area and an inclined portion overlapping with the non-light emission area and connected to respective sides of the flat portion, the flat portion is in contact with the bank structure, the inclined portion is spaced apart from the bank structure, and an inclined angle formed by the bank structure and the inclined portion of the element insulating layer is an acute angle.

This application claims priority to Korean Patent Application No. 10-2025-0043196, filed on Apr. 3, 2025, and all the benefits accruing therefrom under 35 U.S.C. §119, the content of which in its entirety is herein incorporated by reference.

### BACKGROUND

### Field

The present disclosure relates to a display device, an electronic device using the display device, and a method for fabricating the display device.

### Description of the Related Art

With the advancement of the information age, the demand for a display device for displaying an image has increased with various forms. For example, display devices have been applied to various electronic devices such as a smart phone, a digital camera, a laptop computer, a navigator and a smart television. A display device may be a flat panel display device such as a liquid crystal display device, a field emission display device and an organic light emitting display device. The light emitting display device of a flat panel display device may include a light emitting element in which each of pixels of a display panel may self-emit light, thereby displaying an image even without a backlight unit that provides light to the display panel.

Recently, as various electronic devices are developed, the demand for display devices of high resolution is increasing. Since high pixel integration is implemented for display devices of high resolution, a plurality of light emitting elements may be arranged at narrow intervals.

### BRIEF SUMMARY

An object of the present disclosure is to provide a display device capable of providing an image of high resolution, an electronic device using the display device, and a method for fabricating the display device.

Another object of the present disclosure is to provide a display device of high resolution, in which the electrical resistance of the display device is reduced by an increased contact area between a bank structure and a cathode electrode.

The objects of the present disclosure are not limited to those mentioned above and additional objects of the present disclosure, which are not mentioned herein, will be clearly understood by those skilled in the art from the following description of the present disclosure.

Details of the other embodiments are included in the detailed description and drawings.

In an embodiment of the disclosure, a display device including: a substrate including a light emission area and a non-light emission area; a bank structure positioned on the light emission area of the substrate and having an overhang structure; an anode electrode positioned on the bank structure; and an element insulating layer positioned between the bank structure and the anode electrode, wherein the element insulating layer includes a flat portion overlapping the light emission area and an inclined portion overlapping with the non-light emission area and connected to respective sides of the flat portion, the flat portion is in contact with the bank structure, the inclined portion is spaced apart from the bank structure, and an inclined angle formed by the bank structure and the inclined portion of the element insulating layer is an acute angle.

In an embodiment, the inclined angle formed by the bank structure and the inclined portion of the element insulating layer may range from 10° to 50°.

In an embodiment, the bank structure may include a first bank layer; a second bank layer positioned on the first bank layer; and a third bank layer including a tip more protruded toward the non-light emission area than a side of the second bank layer, the flat portion is positioned in contact with the third bank layer, the inclined portion is spaced apart from the third bank layer, and the inclined portion overlaps the tip of the third bank layer.

In an embodiment, the inclined portion may include a first surface directed toward the third bank layer, and a spaced distance between the third bank layer and the first surface increases in a direction away from a contact point at which the third bank layer is in contact with the first surface.

In an embodiment, the spaced distance between the third bank layer and the first surface may range from 1000 Ω to 4000 Ω.

In an embodiment, the display device may further include a pixel defining layer covering an edge of the anode electrode and defining a light emitting opening; and a light emitting layer positioned on the anode electrode, wherein the light emitting layer includes a light emitting flat portion that is in contact with the anode electrode at a portion overlapping the light emitting opening, and a light emitting inclined portion connected to respective sides of the light emitting flat portion and non-overlapping with the light emitting opening.

In an embodiment, the light emitting inclined portion may further include a first surface directed toward the anode electrode, and an inclined angle formed by the anode electrode and the first surface is an acute angle.

In an embodiment, the display device may further include a cathode electrode positioned on the light emitting layer, wherein the third bank layer further includes an upper surface directed toward the element insulating layer, and the upper surface of the third bank layer includes a first portion that is in contact with the flat portion of the element insulating layer and a second portion that is in contact with the cathode electrode.

In an embodiment, the display device may further include an organic pattern positioned between the tip of the third bank layer and the inclined portion of the element insulating layer and spaced apart from the light emitting layer, wherein the organic pattern includes the same material as the light emitting layer.

In an embodiment of the disclosure, a method for fabricating a display device, the method include forming a temporary insulating layer of a forward tapered shape on a bank structure; forming an element insulating layer including a flat portion and an inclined portion; forming a tip of the bank structure; and forming a light emitting element and an element inorganic layer on the bank structure.

In an embodiment, the temporary insulating layer includes a first surface directed toward the bank structure and a side connected to the first surface, and an inclined angle formed by the first surface and the side ranges from 10° to 50°.

In an embodiment, the element insulating layer and the temporary insulating layer may include an inorganic insulating material, and the element insulating layer has a film density different from a film density of the temporary insulating layer.

In an embodiment, the method may further include forming a pixel defining layer positioned on the inclined portion of the element insulating layer, the pixel defining layer including an inorganic insulating material, wherein a film density of the element insulating layer and a film density the pixel defining layer are each higher than a film density of the temporary insulating layer.

In an embodiment, wherein a thickness of the temporary insulating layer may be less than each of a thickness of the element insulating layer and a thickness of the pixel defining layer.

In an embodiment, the forming the tip of the bank structure may include forming the bank structure that includes a first bank layer, a second bank layer, and a third bank layer, the second bank layer includes aluminum, the third bank layer includes titanium, and the third bank layer includes a tip more protruded than a side of the second bank layer.

In an embodiment, the forming the light emitting element and the element inorganic layer on the bank structure includes forming a light emitting layer and a cathode electrode by a photo pattern process without a separate fine metal mask, wherein the light emitting element includes the light emitting layer and the cathode electrode.

In an embodiment of the disclosure, an electronic device include at least one display device including a substrate including a light emission area and a non-light emission area; and at least one of a display module, a processor, a memory, or a power module, which is connected to the at least one display device, wherein the at least one display device includes: a bank structure positioned on the light emission area of the substrate and having an overhang structure; an anode electrode positioned on the bank structure; and an element insulating layer positioned between the bank structure and the anode electrode, wherein the element insulating layer includes a flat portion overlapping the light emission area and an inclined portion overlapping with the non-light emission area and connected to respective sides of the flat portion, the flat portion is in contact with the bank structure, and the inclined portion is spaced apart from the bank structure, and an inclined angle formed by the bank structure and the inclined portion of the element insulating layer is an acute angle.

In the display device, the electronic device using the display device, and the method for fabricating the display device according to the embodiments, a light emitting element is formed on a bank structure, such that a plurality of light emitting elements may be efficiently arranged within a narrow space. Accordingly, an image of high resolution may be provided.

In some aspects, in the display device, the electronic device using the display device, and the method for fabricating the display device according to the embodiments, a space is formed between the bank structure and an inclined portion of an element insulating layer, such that a contact area between a cathode electrode and the bank structure is increased, thereby reducing electrical resistance of the display device.

The effects according to the embodiments of the present disclosure are not limited to those mentioned above and more various effects are included in the following description of the present disclosure.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to an embodiment;

FIG. 2 is a cross-sectional view illustrating a display device according to an embodiment;

FIG. 3 is a plan view illustrating a display layer in FIG. 2;

FIG. 4 is a plan view illustrating arrangement of a plurality of pixels arranged in a display area of FIG. 3;

FIG. 5 is a cross-sectional view illustrating an example of a display layer taken along X1-X1’ of FIG. 4;

FIG. 6 is an enlarged cross-sectional view illustrating a display element layer that overlaps a first light emission area in FIG. 5;

FIG. 7 is an enlarged cross-sectional view illustrating an area ‘A’ in FIG. 6;

FIG. 8 is an enlarged cross-sectional view illustrating an area ‘A’ in FIG. 6 as a comparative example;

FIG. 9 is a cross-sectional view illustrating an example of a display layer taken along X3-X3’ of FIG. 4;

FIG. 10 is a flow chart illustrating a method for fabricating a display element layer of FIG. 5;

FIGS. 11 and 12 are cross-sectional views illustrating step S100 of FIG. 10;

FIGS. 13 to 16 are cross-sectional views illustrating step S200 of FIG. 10;

FIGS. 17 to 19 are cross-sectional views illustrating step S300 of FIG. 10;

FIGS. 20 to 22 are cross-sectional views illustrating step S400 of FIG. 10;

FIG. 23 is a block diagram illustrating an electronic device according to an embodiment; and

FIG. 24 illustrates schematic diagrams of electronic devices according to various embodiments.

### DETAILED DESCRIPTION

Advantages and features of the present disclosure and methods of accomplishing the same may be understood more readily by reference to the following detailed description of embodiments and the accompanying drawings. The present disclosure may, however, be embodied in many different forms and should not be construed as being limited to the embodiments set forth herein. Rather, the example embodiments are provided such that this disclosure will be thorough and complete and will fully convey the concept of the present disclosure to those skilled in the art, and the present disclosure will be defined by the appended claims.

It will be understood that when an element or layer is referred to as being "on” another element or layer, the element or layer can be directly on another element or layer or intervening elements or layers. Like reference numerals refer to like elements throughout the specification. Shapes, sizes, ratios, angles, numbers, and the like disclosed in the drawings for describing embodiments are an example, and the present disclosure is not limited to the illustrated details.

It will be understood that, although the terms first, second, third, and the like may be used herein to describe various elements, these elements should not be limited by these terms. These terms are used to distinguish one element from another element. Thus, a first element discussed below could be termed a second element without departing from the teachings of the present disclosure.

Features of various embodiments of the present disclosure may be partially or entirely coupled to or combined with each other and may be inter-operated and driven in technically various ways. The embodiments may be implemented independently from each other, or may be implemented together in a co-dependent relationship.

Hereinafter, embodiments of the present disclosure will be described in detail with reference to the accompanying drawings.

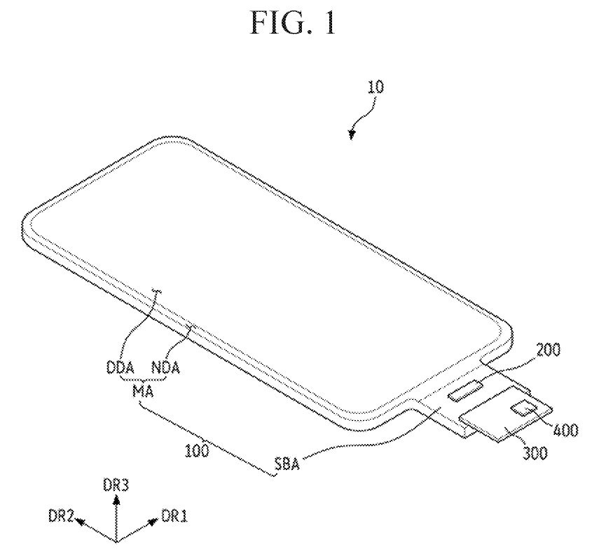

FIG. 1 is a perspective view illustrating a display device according to an embodiment.

Referring to FIG. 1, a display device 10 may be applied to a mobile electronic device such as a mobile phone, a smart phone, a tablet personal computer (PC), a mobile communication terminal, an electronic diary, an electronic book, a portable multimedia player (PMP), a navigator and an ultra-mobile PC (UMPC). For example, the display device 10 may be applied to a television, a laptop computer, a monitor, a signboard or a display unit of Internet of things (IoT). As another example, the display device 10 may be applied to a wearable device such as a smart watch, a watch phone, an eyeglasses-type display and a head mounted display (HMD).

The display device 10 may be formed in a planar shape similar to a rectangular shape. For example, the display device have a planar shape similar to a rectangular shape having a short side in a first direction DR1 and a long side in a second direction DR2. A corner where the short side in the first direction DR1 and the long side in the second direction DR2 meet may be rounded to have a curvature or formed at a right angle. The planar shape of the display device 10 may have another polygonal shape or a shape similar to a circular shape or an oval shape without being limited to the rectangular shape.

The display device 10 may include a display panel 100, a display driver 200, a circuit board 300 and a touch driver 400.

The display panel 100 may include a main area MA and a sub-area SBA. The main area MA may include a display area DDA including pixels for displaying an image and a non-display area NDA positioned near the display area DDA.

The display area DDA may emit light from a plurality of light emission areas or a plurality of opening areas, which will be described. For example, the display panel 100 may include a pixel circuit including switching elements, an element insulating layer defining a light emission area or an opening area, and a self-light emitting element. For example, the self-light emitting element may include at least one of an organic light emitting diode including an organic light emitting layer, a quantum dot light emitting diode (LED) including a quantum dot light emitting layer, an inorganic light emitting diode (inorganic LED) including an inorganic semiconductor, or a micro light emitting diode (micro LED), but is not limited thereto. In the following drawing, the self-light emitting element is illustrated as an organic light emitting diode.

The non-display area NDA may be an outer area of the display area DA. The non-display area NDA may be defined as an edge area of the main area MA of the display panel 100.

The sub-area SBA may be an area extended from one side of the main area MA. The sub-area SBA may include a flexible material capable of being subjected to bending, folding, rolling and the like. In an example in which the sub-area SBA is bent, the sub-area SBA may overlap the main area MA in a thickness direction (e.g., a third direction DR3). The sub-area SBA may include a pad portion connected to the display driver 200 and the circuit board 300. In another embodiment, the sub-area SBA may be omitted, and the display driver 200 and the pad portion may be arranged in the non-display area NDA.

The display driver 200 may output signals and voltages for driving the display panel 100. The display driver 200 may be formed as an integrated circuit (IC) and may be packaged on the display panel 100 by a chip on glass (COG) mode, a chip on plastic (COP) mode or an ultrasonic bonding mode. For example, the display driver 200 may be arranged in the sub-area SBA and may overlap the main area MA in the thickness direction by bending of the sub-area SBA. In another example, the display driver 200 may be packaged on the circuit board 300.

The circuit board 300 may be attached onto the pad portion of the display panel 100 by using an anisotropic conductive film (ACF). The circuit board 300 may be a flexible printed circuit board, a printed circuit board, or a flexible film such as a chip on film.

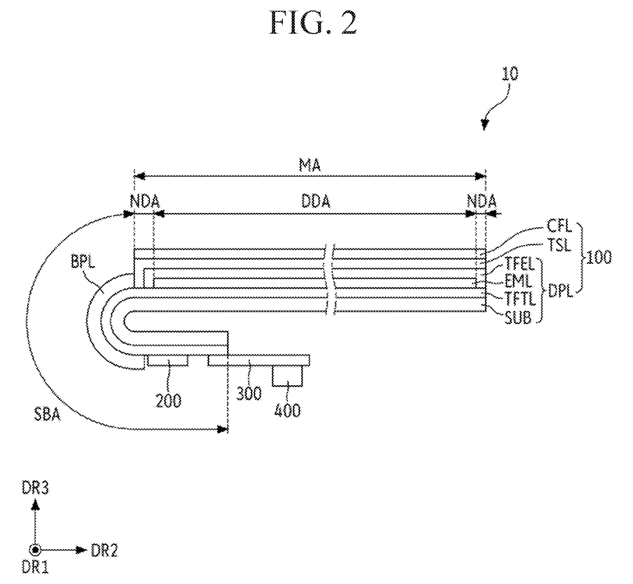

The touch driver 400 may be packaged on the circuit board 300. The touch driver 400 may be connected to a touch sensor layer (‘TSL’ of FIG. 2) for sensing a touch and driving.

FIG. 2 is a cross-sectional view illustrating a display device according to an embodiment.

Referring to FIG. 2, the display panel 100 may include a display layer DPL, a touch sensor layer TSL, and a color filter layer CFL. The display layer DPL may include a substrate SUB, a transistor layer TFTL, a display element layer EML and a thin film encapsulation layer TFEL.

The substrate SUB may be a base substrate or a base member. The substrate SUB may be a flexible substrate capable of being subjected to bending, folding, rolling or the like. For example, the substrate SUB may include a polymer resin such as polyimide (PI), but is not limited thereto. In another embodiment, the substrate SUB may include a glass material or a metal material.

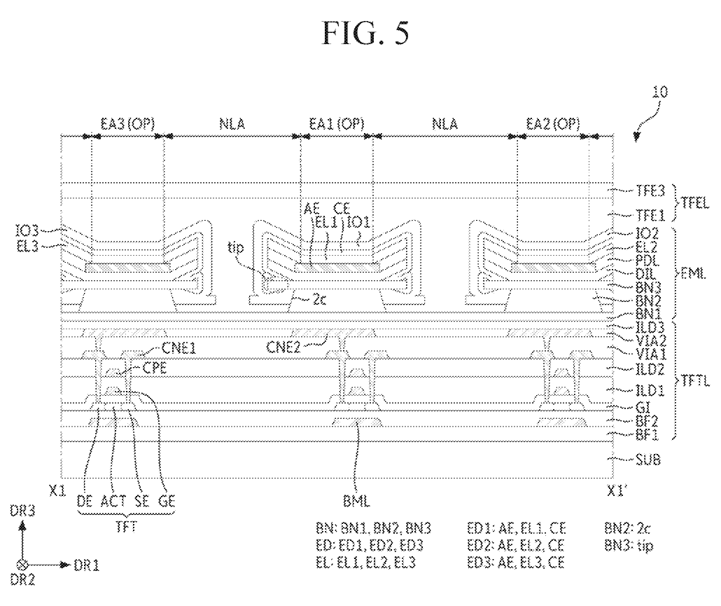

The transistor layer TFTL may be positioned on the substrate SUB. The transistor layer TFTL may be positioned in a portion that overlaps the display area DDA, the non-display area NDA and the sub-area SBA. The transistor layer TFTL may include a plurality of transistors (‘TFT’ of FIG. 5).

The display element layer EML may be positioned on the transistor layer TFTL. The display element layer EML may be positioned in a portion that overlaps the display area DDA. The display element layer EML may include at least one of an organic light emitting diode including an organic light emitting layer, a quantum dot light emitting diode (LED) including a quantum dot light emitting layer, an inorganic light emitting diode (Inorganic LED) including an inorganic semiconductor, or a micro light emitting diode (Micro LED).

The thin film encapsulation layer TFEL may be positioned on the display element layer EML. The thin film encapsulation layer TFEL may be positioned in a portion that overlaps the display area DDA and the non-display area NDA. The thin film encapsulation layer TFEL may cover an upper surface and a side of the display element layer EML and may protect the display element layer EML from external oxygen and moisture. The thin film encapsulation layer TFEL may include at least one inorganic layer and at least one organic layer to encapsulate the display element layer EML. The thin film encapsulation layer TFEL may be omitted depending on the embodiment.

The touch sensor layer TSL may be arranged on the thin film encapsulation layer TFEL. The touch sensor layer TSL may be positioned in a portion that overlaps the display area DDA and the non-display area NDA. The touch sensor layer TSL may sense a user’s touch in a mutual capacitance manner or a self-capacitance manner.

The color filter layer CFL may be positioned on the touch sensor layer TSL. The color filter layer CFL may be positioned in a portion that overlaps the display area DDA and the non-display area NDA. The color filter layer CFL may absorb a portion of light incident from the outside of the display device 10 to reduce reflective light due to external light. Therefore, the color filter layer CFL may prevent color distortion due to reflection of the external light.

As the color filter layer CFL is directly arranged on the touch sensor layer TSL, the display device 10 may be implemented without a separate substrate for the color filter layer CFL. Therefore, a thickness of the display device 10 may be relatively small. The color filter layer CFL may be omitted depending on the embodiment.

As illustrated in FIG. 2, a portion of the display panel 100 that overlaps the sub-area SBA may be bent. In an example in which a portion of the display panel 100 is bent, the display driver 200, the circuit board 300 and the touch driver 400 may overlap the main area MA in the third direction DR3.

When a portion of the display panel 100 is bent, a bending protection layer BPL may protect a lower structure overlapping the sub-area SBA from bending stress.

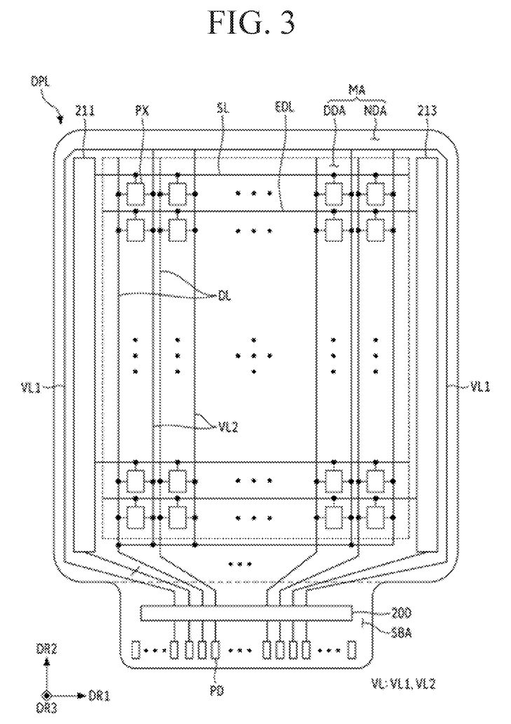

FIG. 3 is a plan view illustrating a display layer in FIG. 2.

Referring to FIG. 3, the display layer DPL may include a plurality of pixels PX in a portion overlapping the display area DDA, a plurality of power lines VL connected to the plurality of pixels PX, a plurality of scan lines SL, a plurality of light emission control lines EDL, and a plurality of data lines DL.

Each of the plurality of scan lines SL may extend in the first direction DR1 and may be spaced apart from each other in the second direction DR2 crossing the first direction DR1. The scan lines SL may be arranged along the second direction DR2. The scan lines SL may sequentially supply scan signals to the plurality of pixels PX.

Each of the light emission control lines EDL may extend in the first direction DR1 and may be spaced apart from each other in the second direction DR2. The light emission control lines EDL may be arranged along the second direction DR2. The light emission control lines EDL may sequentially supply emission signals to the plurality of pixels PX.

The data lines DL may extend in the second direction DR2 and may be spaced apart from each other in the first direction DR1. The data lines DL may be arranged along the first direction DR1. The data lines DL may supply a data voltage to the plurality of pixels PX. The data voltage may determine luminance of each of the plurality of pixels PX.

The power line VL may include a main power line VL1 and a sub-power line VL2. At least one of a first power voltage (high potential voltage) or a second power voltage (low potential voltage) may be transferred to the sub-power line VL2 through the main power line VL1 overlapping the non-display area NDA. Hereinafter, the main power line VL1 and the sub-power line VL2 may be collectively referred to as the power line VL.

The non-display area NDA may surround the display area DDA. The non-display area NDA may include a scan driver 211 and a light emission control driver 213.

The scan driver 211 may be arranged outside one side of the display area DDA or on one side of the non-display area NDA. The scan driver 211 may include a plurality of driving transistors that generate gate signals based on a gate control signal.

The light emission control driver 213 may be arranged outside the other side of the display area DDA or on the other side of the non-display area NDA. The light emission control driver 213 may include a plurality of light emission control transistors that generate light emission signals based on a light emission control signal.

The display layer DPL included In an embodiment may include a display driver 200 and a plurality of pad electrodes PD in a portion that overlaps the sub-area SBA. The plurality of pad electrodes PD may be positioned to be spaced apart from each other in the first direction DR1, and each pad electrode PD may be connected to each different line.

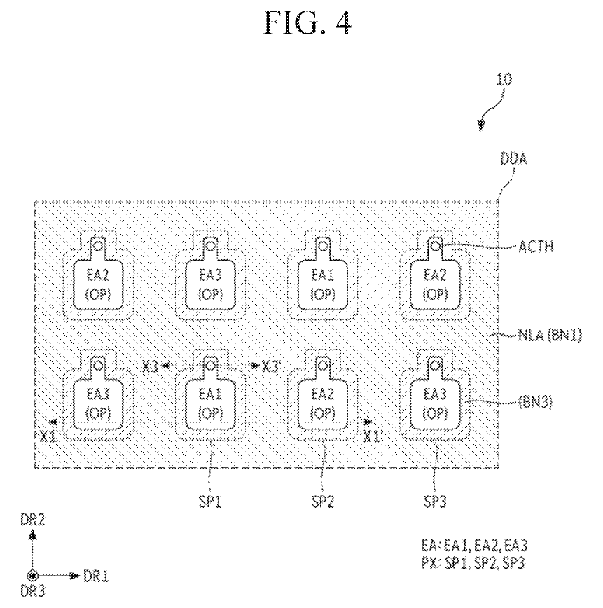

FIG. 4 is a plan view illustrating arrangement of a plurality of pixels arranged in a display area of FIG. 3.

Referring to FIG. 4, the pixel PX according to an embodiment may include a first subpixel SP1, a second subpixel SP2, and a third subpixel SP3, which are positioned in a portion overlapping the display area DDA. The first subpixel SP1, the second subpixel SP2, and the third subpixel SP3 may be spaced apart from one another.

The pixel PX may include a light emission area EA. The light emission area EA may be a portion through which light is emitted. For example, the first subpixel SP1 may include a first light emission area EA1, the second subpixel SP2 may include a second light emission area EA2, and the third subpixel SP3 may include a third light emission area EA3.

In an embodiment, the first light emission area EA1, the second light emission area EA2, and the third light emission area EA3 may emit light of different colors. For example, the first light emission area EA1 may emit red light, the second light emission area EA2 may emit green light, and the third light emission area EA3 may emit blue light, but embodiments of the present disclosure are not limited thereto. According to one embodiment, the first light emission area EA1, the second light emission area EA2, and the third light emission area EA3 may emit the same color.

In an embodiment, the light emission area EA may be defined by the light emitting opening OP. The light emitting opening OP may be defined by the pixel defining layer (‘PDL’ in FIG. 5) to be described later.

On a plane, an anode contact hole ACTH may be positioned at a portion overlapping the light emission area EA. On the plane, the anode contact hole ACTH may be positioned inside the light emission area EA. For convenience of description, although the anode contact hole ACTH is illustrated as being positioned at one side above the light emission area EA, the present specification is not limited thereto. A detailed structure of the anode contact hole ACTH will be described later.

The display device 10 according to an embodiment may include a non-light emission area NLA at a portion that overlaps the display area DDA. The non-light emission area NLA may prevent color mixture of light emitted from the first light emission area EA1, the second light emission area EA2, and the third light emission area EA3.

On a plane, a bank structure BN may be positioned at a portion that overlaps the non-light emission area NLA. On the plane, a third bank layer BN3 included in the bank structure BN may have a shape of a conductive pattern positioned to surround the light emission area EA or the light emitting opening OP. On the plane, the third bank layers BN3 respectively positioned to surround the first to third light emission areas EA1, EA2 and EA3 may be spaced apart from each other.

In some aspects, a first bank layer BN1 included in the bank structure BN may be entirely formed at a portion that overlaps the non-light emission area NLA. On the plane, the first bank layer BN1 may electrically connect the third bank layers BN3 respectively positioned to surround the first to third light emission areas EA1, EA2 and EA3.

FIG. 5 is a cross-sectional view illustrating an example of a display layer taken along X1-X1’ of FIG. 4.

Referring to FIG. 5 in addition to FIGS. 1 - 4, the transistor layer TFTL may be positioned on the substrate SUB. The transistor layer TFTL may include a first buffer layer BF1, a lower metal layer BML, a second buffer layer BF2, a transistor TFT, a gate insulating layer GI, a first insulating layer ILD1, a capacitor electrode CPE, a second insulating layer ILD2, a first connection electrode CNE1, a first via layer VIA1, a second connection electrode CNE2, a second via layer VIA2, and a third insulating layer ILD3.

The first buffer layer BF1 may be positioned on the substrate SUB. The first buffer layer BF1 may include an inorganic layer capable of preventing permeation of the air or moisture. For example, the first buffer layer BF1 may include a plurality of inorganic layers that are alternately stacked.

The lower metal layer BML may be positioned on the first buffer layer BF1. The lower metal layer BML may include a conductive metal, and for example, may be formed as a single layer or multi-layer formed of any one of molybdenum (Mo), aluminum (Al), chromium (Cr), gold (Au), titanium (Ti), nickel (Ni), neodymium (Nd) and copper (Cu), or their alloy.

The second buffer layer BF2 may cover the first buffer layer BF1 and the lower metal layer BML. The second buffer layer BF2 may include an inorganic layer capable of preventing permeation of the air or moisture. For example, the second buffer layer BF2 may include a plurality of inorganic layers that are alternately stacked.

The transistor TFT may be arranged on the second buffer layer BF2, and the transistor TFT may constitute a pixel circuit. For example, the transistor TFT may be a driving transistor or a switching transistor of the pixel circuit.

The transistor TFT may include an active layer ACT, a source electrode SE, a drain electrode DE, and a gate electrode GE.

The active layer ACT may be positioned on the second buffer layer BF2. The active layer ACT may overlap the gate electrode GE in the third direction DR3 and may be insulated from the gate electrode GE by the gate insulating layer GI. The source electrode SE and the drain electrode DE may be portions in which a portion of the active layer ACT is conductive.

The gate insulating layer GI may be positioned on the active layer ACT. The gate insulating layer GI may cover the active layer ACT and the second buffer layer BF2 and may insulate the active layer ACT from the gate electrode GE. The gate insulating layer GI may include a contact hole through which the first connection electrode CNE1 passes.

The gate electrode GE may be positioned on the gate insulating layer GI. The gate electrode GE may overlap the active layer ACT with the gate insulating layer GI. The gate insulating layer GI may be interposed between the gate electrode GE and the active layer ACT.

The gate electrode GE may include a conductive metal, and for example, may be formed as a single layer or multi-layer formed of any one of molybdenum (Mo), aluminum (Al), chromium (Cr), gold (Au), titanium (Ti), nickel (Ni), neodymium (Nd) and copper (Cu), or their alloy.

The first insulating layer ILD1 may cover the gate electrode GE and the gate insulating layer GI. The first insulating layer ILD1 may include a contact hole through which the first connection electrode CNE1 passes. The contact hole of the first insulating layer ILD1 may be connected to the contact hole of the gate insulating layer GI and a contact hole of the second insulating layer ILD2.

The capacitor electrode CPE may be positioned on the first insulating layer ILD1. The capacitor electrode CPE may overlap the gate electrode GE in the third direction DR3. The capacitor electrode CPE and the gate electrode GE may form a capacitance.

The second insulating layer ILD2 may cover the capacitor electrode CPE and the first insulating layer ILD1. The second insulating layer ILD2 may include a contact hole through which the first connection electrode CNE1 passes. The contact hole of the second insulating layer ILD2 may be connected to the contact hole of the first insulating layer ILD1 and the contact hole of the gate insulating layer GI.

The first connection electrode CNE1 may be positioned on the second insulating layer ILD2. The first connection electrode CNE1 may electrically connect the drain electrode DE of the transistor TFT with the second connection electrode CNE2. The first connection electrode CNE1 may be inserted into the contact hole formed in the first insulating layer ILD1, the second insulating layer ILD2, and the gate insulating layer GI and thus may be in contact with the drain electrode DE of the transistor TFT.

The first via layer VIA1 may be positioned on the first connection electrode CNE1 and the second insulating layer ILD2. The first via layer VIA1 may planarize the lower structure. The first via layer VIA1 may include a contact hole through which the second connection electrode CNE2 passes.

The first via layer VIA1 may include an organic insulating material. For example, the first via layer VIA1 may include an acrylic resin, polyimide, polyamide, benzocyclobutene, phenolic resin, and the like.

The second connection electrode CNE2 may be positioned on the first via layer VIA1. The second connection electrode CNE2 may be positioned at a portion that overlaps the light emission area EA. The second connection electrode CNE2 may be inserted into the contact hole formed in the first via layer VIA1 and thus may be in contact with the first connection electrode CNE1.

The second via layer VIA2 may be positioned on the first via layer VIA1. The second via layer VIA2 may planarize a step difference formed by the second connection electrode CNE2.

The second via layer VIA2 may include an organic material. For example, the second via layer VIA2 may include an acrylic resin, a silicon resin, a silicon acrylic resin, an epoxy resin, polyimide, polyamide, benzocyclobutene, a phenolic resin, and the like.

The third insulating layer ILD3 may be positioned on the second via layer VIA2. The third insulating layer ILD3 may assist the second via layer VIA2 such that an outgas caused by an organic material of the second via layer VIA2 does not permeate into the display element layer EML.

The third insulating layer ILD3 may include an inorganic insulating material. For example, the third insulating layer ILD3 may include at least one of silicon nitride, silicon oxide, or silicon oxynitride.

The display element layer EML may be arranged on the transistor layer TFTL. The display element layer EML may include a bank structure BN, an element insulating layer DIL, a pixel defining layer PDL, a light emitting element ED, and an element inorganic layer IO.

The bank structure BN may be arranged on the third insulating layer ILD3. The bank structure BN may be positioned at a portion that overlaps the light emission area EA and the non-light emission area NLA.

The bank structure BN may assist the first to third light emitting elements ED1, ED2 and ED3 to be formed at portions that overlap the first to third light emission areas EA1, EA2 and EA3, respectively. In some aspects, the bank structure BN may assist the cathode electrodes CE, which is positioned to be spaced apart from the first to third light emission areas EA1, EA2 and EA3, to be electrically connected to the first to third light emission areas.

The bank structure BN may include a first bank layer BN1, a second bank layer BN2, and a third bank layer BN3. The first bank layer BN1, the second bank layer BN2, and the third bank layer BN3 may be sequentially stacked in the third direction DR3.

The first bank layer BN1 may be positioned on the third insulating layer ILD3. The first bank layer BN1 may cover the third insulating layer ILD3 at a portion that overlaps the light emission area EA and the non-light emission area NLA.

The first bank layer BN1 may be entirely formed at a portion that overlaps the light emission area EA and the non-light emission area NLA. The first bank layer BN1 may assist to apply a second power voltage (low potential voltage) to the cathode electrode CE.

The first bank layer BN1 may include a conductive metal having etching resistance. For example, the first bank layer BN1 may include titanium (Ti).

The second bank layer BN2 may be positioned to be in contact with the first bank layer BN1 at a portion that overlaps the light emission area EA. The second bank layer BN2 may be formed as a plurality of second bank layers, and the plurality of second bank layers BN2 may be spaced apart from each other in the first direction DR1. In other words, the plurality of second bank layers BN2 may be positioned at portions that overlap the first to third light emission areas EA1, EA2 and EA3, respectively, and each of the second bank layers BN2 may be formed in an island-shaped conductive pattern.

The second bank layer BN2 positioned at a portion overlapping the first light emission area EA1, the second bank layer BN2 positioned at a portion overlapping the second light emission area EA2, and the second bank layer BN2 positioned at a portion overlapping the third light emission area EA3 may be electrically connected by the first bank layer BN1.

The second bank layer BN2 may include a metal having high electrical conductivity. For example, the second bank layer BN2 may include aluminum (Al).

The third bank layer BN3 may be positioned to be in contact with the second bank layer BN2. The third bank layer BN3 may be provided as a plurality of third bank layers, and the plurality of third bank layers BN3 may be spaced apart from each other in the first direction DR1. In other words, the plurality of third bank layers BN3 may be positioned at portions that overlap the first to third light emission areas EA1, EA2, and EA3, respectively, and each of the third bank layers BN3 may be formed in an island-shaped conductive pattern.

The third bank layer BN3 may include a conductive metal having etching resistance. For example, the third bank layer BN3 may be titanium (Ti).

The third bank layer BN3 positioned at a portion overlapping the first light emission area EA1, the third bank layer BN3 positioned at a portion overlapping the second light emission area EA2, and the third bank layer BN3 positioned at a portion overlapping the third light emission area EA3 may be electrically connected through the second bank layer BN2 and the first bank layer BN1.

In an embodiment, the second bank layer BN2 may include a side 2c directed toward the non-light emission area NLA, and the third bank layer BN3 may include a tip more protruded in the first direction DR1 than the side 2c of the second bank layer BN2. Accordingly, the side 2c of the second bank layer BN2 and the tip of the third bank layer BN3 may form an undercut. That is, the bank structure BN according to an embodiment may have an overhang structure.

In the display device 10 according to an embodiment, as the bank structure BN includes a tip, the first light emitting element ED1, the second light emitting element ED2, and the third light emitting element ED3, which are spaced apart from one another, may be formed without a separate fine metal mask in a fabricating process. The fabricating process will be described later.

The element insulating layer DIL may be positioned on the third bank layer BN3. The element insulating layer DIL may cover the third bank layer BN3 and may overlap the tip of the third bank layer BN3 in the third direction DR3.

The element insulating layer DIL may space apart and insulate the bank structure BN from the anode electrode AE so as not to be in contact with each other.

The element insulating layer DIL may include an inorganic insulating material. For example, the element insulating layer DIL may include at least one of silicon nitride, silicon oxide, or silicon oxynitride.

In an embodiment, the element insulating layer DIL may include a portion that is in contact with the third bank layer BN3 and a portion spaced apart from the third bank layer BN3. A detailed description of the element insulating layer DIL will be given later.

The light emitting element ED may be positioned on the element insulating layer DIL and the bank structure BN.

The display device 10 according to an embodiment may be applied to an electronic device of high resolution. Accordingly, the plurality of light emitting elements ED included in the display device 10 may be required to be arranged while making sure of an appropriate spaced distance within a narrow area. Accordingly, in the display device 10 according to an embodiment, the light emitting element ED may be positioned on the bank structure BN, such that the plurality of light emitting elements ED may be efficiently arranged within a narrow area.

The light emitting element ED may include a first light emitting element ED1 arranged in the first light emission area EA1, a second light emitting element ED2 arranged in the second light emission area EA2, and a third light emitting element ED3 arranged in the third light emission area EA3. The first light emitting element ED1, the second light emitting element ED2, and the third light emitting element ED3 may be spaced apart from one another.

In an embodiment, the first light emitting element ED1 may include an anode electrode AE, a first light emitting layer EL1, and a cathode electrode CE, the second light emitting element ED2 may include an anode electrode AE, a second light emitting layer EL2, and a cathode electrode CE, and the third light emitting element ED3 may include an anode electrode AE, a third light emitting layer EL3, and a cathode electrode CE.

The first light emitting element ED1, the second light emitting element ED2, and the third light emitting element ED3 may emit light of different colors. For example, the first light emitting element ED1 may emit red light, the second light emitting element ED2 may emit green light, and the third light emitting element ED3 may emit blue light. Colors emitted by the first light emitting element ED1, the second light emitting element ED2, and the third light emitting element ED3 may be determined by the first light emitting layer EL1, the second light emitting layer EL2, and the third light emitting layer EL3.

The anode electrode AE may be positioned on the element insulating layer DIL. The anode electrode AE may be positioned at a portion that overlaps the light emission area EA and the light emitting opening OP.

The anode electrode AE may have a stacked film structure in which a material layer such as indium-tin-oxide (ITO), indium-zinc-oxide (IZO), zinc oxide (ZnO), and indium oxide (In₂O₃), and a reflective material layer such as silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), or their mixture are stacked. For example, the anode electrode AE may have a multi-layered structure of ITO/Mg, ITO/MgF, ITO/Ag, and ITO/Ag/ITO, but is not limited thereto.

The pixel defining layer PDL may be positioned on the element insulating layer DIL. The pixel defining layer PDL may define the light emitting opening OP, and the pixel defining layer PDL may expose the anode electrode AE at a portion that overlaps the light emitting opening OP. In other words, the pixel defining layer PDL may be positioned to surround the light emitting opening OP and may cover an edge of the anode electrode AE.

The pixel defining layer PDL may include an inorganic insulating material. For example, the pixel defining layer PDL may include at least one of silicon nitride, silicon oxide, or silicon oxynitride.

The light emitting layer EL may be positioned on the anode electrode AE. The light emitting layer EL may be positioned at a portion that overlaps the light emission area EA and the non-light emission area NLA. The light emitting layer EL may overlap the bank structure BN, the element insulating layer DIL, and the pixel defining layer PDL in the third direction DR3. The light emitting layer EL may cover the anode electrode AE and the pixel defining layer PDL.

The light emitting layer EL may include first to third light emitting layers EL1, EL2 and EL3. For example, the first light emitting layer EL1 may be positioned on the anode electrode AE at a portion that overlaps the first light emission area EA1, the second light emitting layer EL2 may be positioned on the anode electrode AE at a portion that overlaps the second light emission area EA2, and the third light emitting layer EL3 may be positioned on the anode electrode AE at a portion that overlaps the third light emission area EA3.

The first to third light emitting layers EL1, EL2 and EL3 may be organic light emitting layers formed of organic materials. The first to third light emitting layers EL1, EL2 and EL3 may include all materials that are commonly used.

The first light emitting layer EL1, the second light emitting layer EL2, and the third light emitting layer EL3 may emit light of different colors. For example, the first light emitting layer EL1 may emit red light, the second light emitting layer EL2 may emit green light, and the third light emitting layer EL3 may emit blue light, but embodiments of the present disclosure are not limited thereto.

As the display device 10 according to an embodiment includes the bank structure BN having an overhang structure, the first to third light emitting layers EL1, EL2 and EL3, which are spaced apart from one another, may be formed at a portion that overlaps each of the first to third light emission areas EA1, EA2 and EA3, without a separate fine metal mask in the fabricating process. The first to third light emitting layers EL1, EL2, and EL3 may be formed by performing a photo pattern process. The fabricating process will be described later.

The cathode electrode CE may be positioned on the light emitting layer EL. The cathode electrode CE may be positioned at a portion that overlaps the light emission area EA and the non-light emission area NLA. The cathode electrode CE may entirely cover the light emitting layer EL.

The cathode electrode CE may be electrically connected to the third bank layer BN3. In some aspects, the cathode electrode CE may be electrically connected to the second bank layer BN2 and the first bank layer BN1 through the third bank layer BN3.

As the cathode electrode CE includes metal having high electrical conductivity and a transparent conductive material, light generated in the first to third light emitting layers EL1, EL2 and EL3 may be emitted. For example, the cathode electrode CE may include a material layer having a small work function, such as Li, Ca, LiF/Ca, LiF/Al, Al, Mg, Ag, Pt, Pd, Ni, Au Nd, Ir, Cr, BaF, Ba or their compound or mixture (e.g., a mixture of Ag and Mg).

In an embodiment, the cathode electrode CE positioned at a portion overlapping the first light emission area EA1, the cathode electrode CE positioned at a portion overlapping the second light emission area EA2, and the cathode electrode CE positioned at a portion overlapping the third light emission area EA3 may be spaced apart from one another. The cathode electrodes CE positioned to be spaced apart from one another in each of the first to third light emission areas EA1, EA2 and EA3 may be electrically connected to one another through the bank structure BN.

The display device 10 according to an embodiment may enable the light emitting layer EL to emit light by applying a first power voltage (high potential voltage) to the anode electrode AE and applying a second power voltage (low potential voltage) to the cathode electrode CE.

The element inorganic layer IO may be positioned on the light emitting element ED. The element inorganic layer IO may completely cover the light emitting element ED and prevent oxygen or moisture from being permeated into the light emitting element ED.

The element inorganic layer IO may include an inorganic insulating material. For example, the element inorganic layer IO may include any one of silicon nitride, silicon oxide, and silicon oxynitride.

The element inorganic layer IO may include a first element inorganic layer IO1, a second element inorganic layer IO2, and a third element inorganic layer IO3. The first element inorganic layer IO1 may be arranged on the first light emitting element ED1 in the first light emission area EA1, the second element inorganic layer IO2 may be arranged on the second light emitting element ED2 in the second light emission area EA2, and the third element inorganic layer IO3 may be positioned on the third light emitting element ED3 in the third light emission area EA3. The first element inorganic layer IO1, the second element inorganic layer IO2, and the third element inorganic layer IO3 may be spaced apart from one another at a portion that overlaps the non-light emission area NLA.

Although the first element inorganic layer IO1, the second element inorganic layer IO2, and the third element inorganic layer IO3 are illustrated as being formed on the same layer, in the fabricating process of the display device 10, the first element inorganic layer IO1 may be formed after the first light emitting element ED1 is formed, the second element inorganic layer IO2 may be formed after the second light emitting element ED2 is formed, and the third element inorganic layer IO3 may be formed after the third light emitting element ED3 is formed. The fabricating process will be described later.

The thin film encapsulation layer TFEL may be positioned on the display element layer EML. The thin film encapsulation layer TFEL may include an organic encapsulation layer TFE1 and an inorganic encapsulation layer TFE3.

The organic encapsulation layer TFE1 according to an embodiment may be positioned on the element inorganic layer IO. For example, the organic encapsulation layer TFE1 may cover the first element inorganic layer IO1, the second element inorganic layer IO2, and the third element inorganic layer IO3 in entire contact with these layers.

The organic encapsulation layer TFE1 may planarize a step difference formed along a profile of a lower structure. The organic encapsulation layer TFE1 may fill a spaced portion between the element inorganic layer IO and the first bank layer BN1 at a portion that overlaps the non-light emission area NLA.

The organic encapsulation layer TFE1 may include a polymer-based material. For example, the organic encapsulation layer TFE1 may include an acrylic resin, a silicon-based resin, an epoxy-based resin, a silicon acrylic resin, polyimide, polyethylene, and the like.

The inorganic encapsulation layer TFE3 may be positioned on the organic encapsulation layer TFE1. The inorganic encapsulation layer TFE3 may protect the lower structure such that moisture and oxygen does not permeate into the lower structure. The inorganic encapsulation layer TFE3 may be omitted depending on the embodiment.

The inorganic encapsulation layer TFE3 may include an inorganic insulating material. For example, the inorganic encapsulation layer TFE3 may include any one of silicon nitride, silicon oxide, and silicon oxynitride.

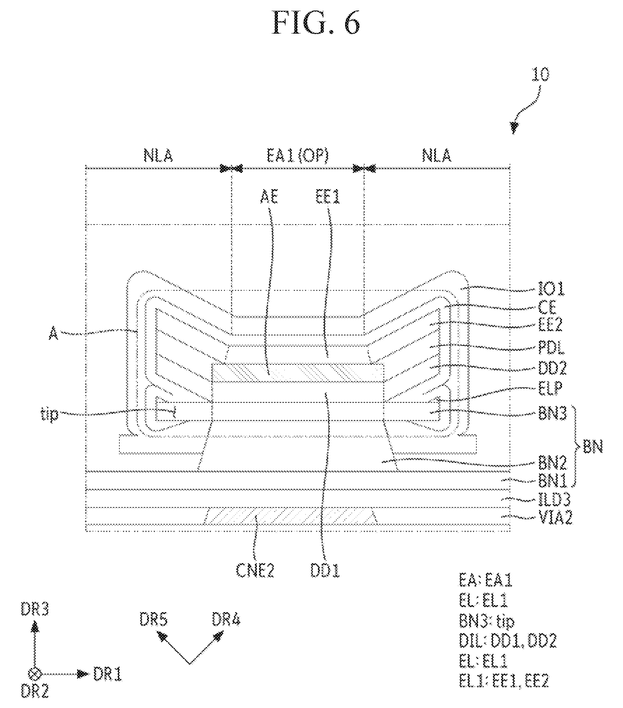

FIG. 6 is an enlarged cross-sectional view illustrating a display element layer that overlaps a first light emission area in FIG. 5. Hereinafter, the first light emission area EA1 may be described as the light emission area EA.

Referring to FIG. 6, the element insulating layer DIL according to an embodiment may include a flat portion DD1 and an inclined portion DD2.

The flat portion DD1 of the element insulating layer DIL may be positioned at a part that overlaps the light emitting opening OP and the light emission area EA. The flat portion DD1 may be a portion that is in contact with the third bank layer BN3 of the bank structure BN. The flat portion DD1 may refer to a portion of the element insulating layer DIL, which has a surface flat in the first direction DR1. The flat portion DD1 may refer to a middle portion of the element insulating layer DIL.

The inclined portion DD2 of the element insulating layer DIL may be positioned at a portion that overlaps the non-light emission area NLA. The inclined portion DD2 may be spaced apart from the third bank layer BN3 of the bank structure BN in the third direction DR3, and the inclined portion DD2 may overlap the tip of the third bank layer BN3 in the third direction DR3.

The inclined portion DD2 may be a portion extended from the flat portion DD1 and may mean an edge portion of the element insulating layer DIL. The inclined portion DD2 may form a tapered angle with the third bank layer BN3. Accordingly, a space may be included between the inclined portion DD2 and the tip of the third bank layer BN3. The inclined portion DD2 may include a surface inclined in a fourth direction DR4 or a fifth direction DR5. A detailed description of the inclined portion DD2 will be given later.

The organic pattern ELP may be positioned on the tip of the third bank layer BN3 at a portion that overlaps the non-light emission area NLA. The organic pattern ELP may include the same material as the light emitting layer EL, and the organic pattern ELP may be spaced apart from the light emitting layer EL.

The organic pattern ELP may be positioned to be in contact with the third bank layer BN3 on the third bank layer BN3. The organic pattern ELP may overlap the inclined portion DD2 of the element insulating layer DIL in the third direction DR3. In other words, the organic pattern ELP may be positioned within a space formed between the inclined portion DD2 of the element insulating layer DIL and the third bank layer BN3.

The pixel defining layer PDL may be positioned to be in contact with the inclined portion DD2 of the element insulating layer DIL on the inclined portion DD2 of the element insulating layer DIL. The pixel defining layer PDL may include a surface parallel with the inclined portion DD2 of the element insulating layer DIL. That is, the pixel defining layer PDL may include a surface inclined in the fourth direction DR4 or the fifth direction DR5.

The light emitting layer EL may include a light emitting flat portion EE1 and a light emitting inclined portion EE2.

The light emitting flat portion EE1 of the light emitting layer EL may be positioned at a portion that overlaps the light emitting opening OP and the light emission area EA. The light emitting flat portion EE1 may be a portion that is in contact with the anode electrode AE. The light emitting flat portion EE1 may include a surface flat in the first direction DR1. The light emitting flat portion EE1 may mean a middle portion of the light emitting layer EL.

In an embodiment, the light emitting flat portion EE1 may include a surface parallel with the flat portion DD1 of the element insulating layer DIL.

The light emitting inclined portion EE2 of the light emitting layer EL may be positioned at a portion that overlaps the non-light emission area NLA. The light emitting inclined portion EE2 may overlap the tip of the third bank layer BN3 in the third direction DR3. The light emitting inclined portion EE2 may be a portion extended from the light emitting flat portion EE1 and may mean an edge portion of the light emitting layer EL.

In an embodiment, the light emitting inclined portion EE2 may include a surface parallel with the inclined portion DD2 of the element insulating layer DIL. For example, the light emitting inclined portion EE2 may include a surface inclined in the fourth direction DR4 or the fifth direction DR5.

The cathode electrode CE may cover the light emitting flat portion EE1 and the light emitting inclined portion EE2 in contact with these portions. Accordingly, the cathode electrode CE may cover the inclined portion DD2 of the element insulating layer DIL and the tip of the third bank layer BN3 in contact with these portions.

As described herein, the cathode electrode CE may be in contact with the bank structure BN, and thus may be electrically connected to the bank structure BN.

For example, in the display device 10 of an embodiment, when a contact area between the cathode electrode CE and the bank structure BN is lowered to a certain range or less, reliability defects such as a power supply failure or a luminance failure of the display device 10 may be caused. In some aspects, in the display device 10 of an embodiment, as the contact area between the cathode electrode CE and the bank structure BN increases, electrical resistance of the display device 10 may decrease.

Therefore, the display device 10 according to an embodiment is to increase the contact area between the third bank layer BN3 and the cathode electrode CE by forming a space between the tip of the third bank layer BN3 and the element insulating layer DIL.

For convenience of description, the display element layer overlapping the first light emission area EA1 is illustrated as being enlarged, but the structure of the display element layer overlapping the second light emission area EA2 and the third light emission area EA3 may include the same structure as the display element layer overlapping the first light emission area EA1.

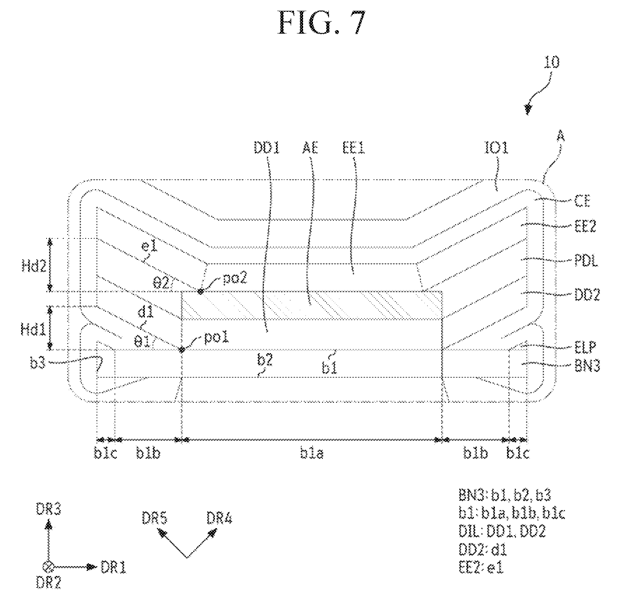

FIG. 7 is an enlarged cross-sectional view illustrating an area ‘A’ in FIG. 6.

Referring to FIG. 7 in addition to FIGS. 1 to 6, in an embodiment, the third bank layer BN3 may include an upper surface b1, a lower surface b2, and a side b3. The upper surface b1 of the third bank layer BN3 may be a surface facing the element insulating layer DIL, the lower surface b2 may be a surface opposite to the upper surface b1, and the side b3 may be a surface connecting the upper surface b1 to the lower surface b2.

For example, the upper surface b1 of the third bank layer BN3 may include a first portion b1a, a second portion b1b, and a third portion b1c in accordance with a contact structure. The first portion b1a may be a portion that is in contact with the element insulating layer DIL, the second portion b1b may be a portion that is in contact with the cathode electrode CE, and the third portion b1c may be a portion that is in contact with the organic pattern ELP. The second portion b1b may be positioned between the first portion b1a and the third portion b1c.

The inclined portion DD2 of the element insulating layer DIL may include a first surface d1 facing the third bank layer BN3. A spaced distance Hd1 between the inclined portion DD2 of the element insulating layer DIL and the third bank layer BN3 may increase in a direction away from a contact point po1 between the first surface d1 and the third bank layer BN3.

For example, the spaced distance Hd1 between the first surface d1 of the inclined portion DD2 and the third bank layer BN3 may have a value of 1000 Ω or more and 4000 Ω or less.

A tapered angle may be formed between the inclined portion DD2 of the element insulating layer DIL and the third bank layer BN3. A detailed description of the tapered angle will be given later.

A deposition incident angle included in the process of forming the light emitting layer EL in the fabricating process of the display device 10 may have a value of 50° or more. That is, in the process of forming the light emitting layer EL, a material for forming the light emitting layer EL may be deposited on the anode electrode AE at an angle of 50° or more with respect to a line parallel with the first direction DR1.

The light emitting layer EL according to an embodiment may be formed through a photo pattern process without a separate fine metal mask in the fabricating process. This may mean that the material for forming the light emitting layer EL is not only formed on the anode electrode AE but also formed on the tip of the third bank layer BN3 and the first bank layer BN1.

As described herein, for the display device 10, embodiments of the present disclosure may maximize the contact area between the third bank layer BN3 and the cathode electrode CE in a space formed between the third bank layer BN3 and the inclined portion DD2 of the element insulating layer DIL. That is, the display device 10 of an embodiment may maximize an area of the second portion b1b of the upper surface b1 of the third bank layer BN3.

Accordingly, the tapered angle formed between the third bank layer BN3 and the inclined portion DD2 of the element insulating layer DIL according to an embodiment may include an angle smaller than the deposition incident angle in the process of forming the light emitting layer EL.

An inclined angle θ1 formed by the first surface d1 of the inclined portion DD2 and the upper surface b1 of the third bank layer BN3 according to an embodiment may be an acute angle. For example, the inclined angle θ1 may range from 10° to 50°.

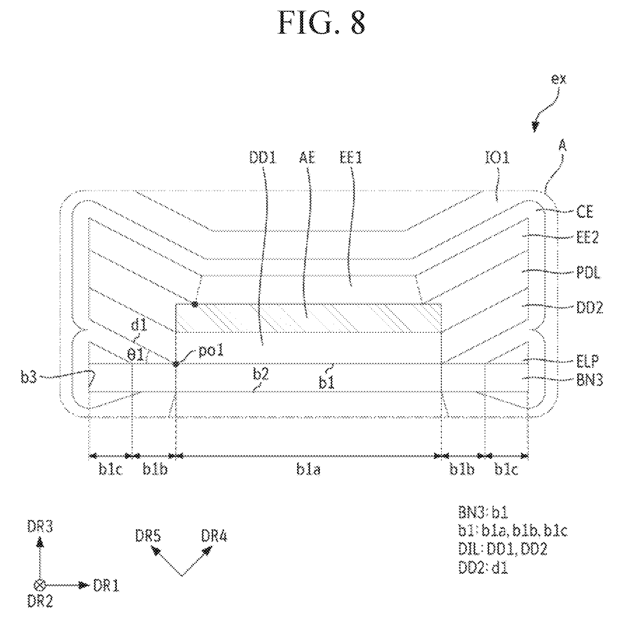

FIG. 8 is an enlarged cross-sectional view illustrating an area ‘A’ in FIG. 6 as a comparative example.

Referring to FIGS. 7 and 8, for example, the inclined angle θ1 formed by the first surface d1 of the inclined portion DD2 and the third bank layer BN3, which is included in the comparative example (ex), may have a value of 50° or more.

Accordingly, in the fabricating process, the material for forming the light emitting layer EL included in the comparative example (ex) may be deposited in the space formed between the inclined portion DD2 of the element insulating layer DIL and the third bank layer BN3 relatively more than the material for forming the light emitting layer EL included in the display device 10. In other words, an area of the second portion b1b included in the comparative example (ex) may be smaller than an area of the second portion b1b included in the display device 10.

As a result, it may be important that the inclined angle θ1 formed by the first surface d1 of the inclined portion DD2 and the upper surface b1 of the third bank layer BN3, which are included in the display device 10, is to be 50° or less.

Although not illustrated, for example, when the inclined angle θ1 formed by the first surface d1 of the inclined portion DD2 and the third bank layer BN3, which are included in the comparative example (ex), has a value of 10° or less, the material for forming the light emitting layer EL and the material for forming the cathode electrode CE may not be formed in the space formed between the third bank layer BN3 and the inclined portion DD2 of the element insulating layer DIL. This may be caused by step coverage characteristics of the process of forming the light emitting layer EL and the process of forming the cathode electrode CE.

Accordingly, it may be important that the inclined angle θ1 formed by the first surface d1 of the inclined portion DD2 and the upper surface b1 of the third bank layer BN3, which are included in the display device 10, is to be 10° or more.

Referring back to FIG. 7, the light emitting inclined portion EE2 of the light emitting layer EL may include a first surface e1 facing the pixel defining layer PDL. A distance Hd2 between the anode electrode AE and the first surface e1 of the light emitting inclined portion EE2 may increase in a direction away from a contact point po2 between the first surface e1 and the anode electrode AE.

An inclined angle θ2 formed by the first surface e1 of the light emitting inclined portion EE2 and the anode electrode AE according to an embodiment may be an acute angle. For example, the inclined angle θ2 may have a range of 10° to 50°.

The light emitting inclined portion EE2 of an embodiment may be covered along a shape of the inclined portion DD2 of the element insulating layer DIL during the fabricating process. Accordingly, the inclined angle θ2 formed by the anode electrode AE and the light emitting inclined portion EE2 of an embodiment may include a tapered angle similar to the inclined angle θ1 formed by the third bank layer BN3 and the inclined portion DD2.

The cathode electrode CE of an embodiment may be covered with a uniform thickness along the profile of the lower structure. The meaning of the uniform thickness may include a value of 10% or less of a process error. A redundant description will be omitted.

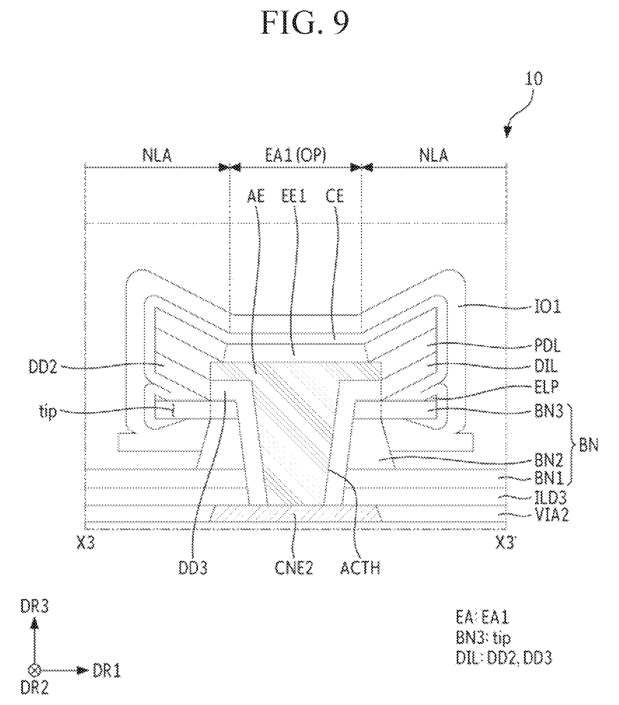

FIG. 9 is a cross-sectional view illustrating an example of a display layer taken along X3-X3’ of FIG. 4. FIG. 9 illustrates a cross-sectional structure of a display element layer EML that overlaps an anode contact hole ACTH. Hereinafter, a common description will be omitted, and characteristics of the display element layer EML overlapping the anode contact hole ACTH will be described.

Referring to FIG. 9 in addition to FIGS. 1 - 8, in an embodiment, the anode contact hole ACTH may be formed such that the anode contact hole ACTH overlaps the light emission area EA.

In an embodiment, the anode contact hole ACTH may be positioned at a portion that overlaps the light emitting opening OP defined by the pixel defining layer PDL. The anode contact hole ACTH may be formed by passing through the bank structure BN, the element insulating layer DIL, and the third insulating layer ILD3, and the second connection electrode CNE2 may be exposed at a portion that overlaps the anode contact hole ACTH.

At a portion that overlaps the anode contact hole ACTH, the anode electrode AE may be in contact with and electrically connected to the second connection electrode CNE2. The anode electrode AE may be electrically connected to the transistor TFT through the second connection electrode CNE2.

In an embodiment, the element insulating layer DIL may include a contact insulating portion DD3 at a portion that overlaps the anode contact hole ACTH. The anode electrode AE may be spaced apart from the first bank layer BN1, the second bank layer BN2, and the third bank layer BN3 with the contact insulating portion DD3. The contact insulating portion DD3 may be interposed between the anode electrode AE and the first to third bank layers BN1 to BN3. Accordingly, the anode electrode AE and the bank structure BN may be insulated from each other at a portion that overlaps the anode contact hole ACTH.

In an embodiment, the first bank layer BN1, the second bank layer BN2, the third bank layer BN3, and the element insulating layer DIL may be positioned to surround the anode contact hole ACTH. In other words, the tip of the third bank layer BN3 and the inclined portion DD2 of the element insulating layer DIL may be positioned to surround the anode contact hole ACTH. Other redundant descriptions will be omitted.

For convenience of description, the structure and characteristics of the anode contact hole ACTH overlapping the first light emission area EA1 have been illustrated and described, but the structure and characteristics of the anode contact hole ACTH overlapping the second light emission area EA2 and the third light emission area EA3 may be the same as the structure and characteristics of the anode contact hole ACTH overlapping the first light emission area EA1.

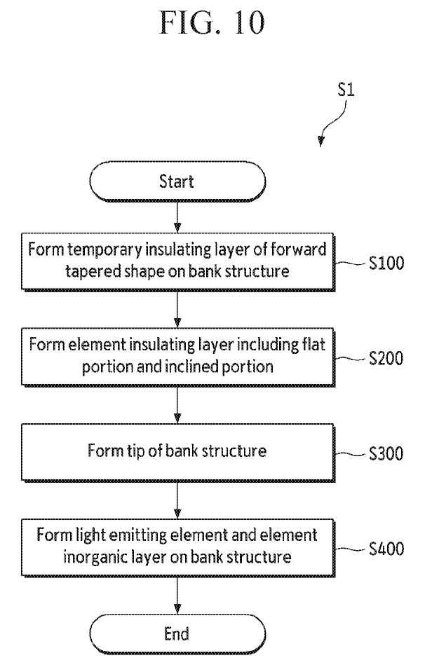

FIG. 10 is a flow chart illustrating a method for fabricating a display element layer of FIG. 5.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

Referring to FIG. 10 in addition to FIGS. 1 - 9, a fabricating method S1 of the display element layer EML included in the display device 10 according to an embodiment may include a step S100 of forming a temporary insulating layer of a forward tapered shape on a bank structure, a step S200 of forming an element insulating layer including a flat portion and an inclined portion, a step S300 of forming a tip of the bank structure, a step S400 of forming a light emitting element and an element inorganic layer on the bank structure.

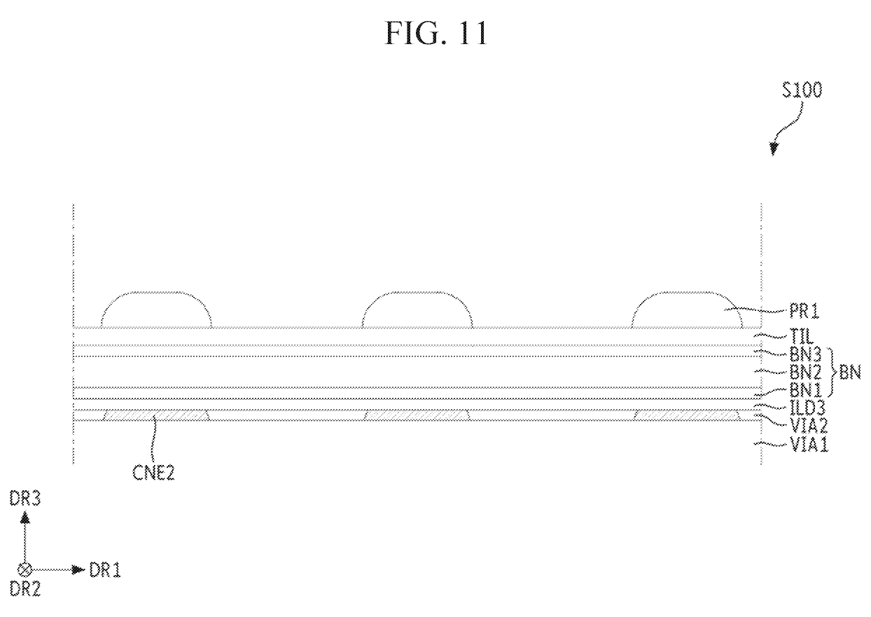

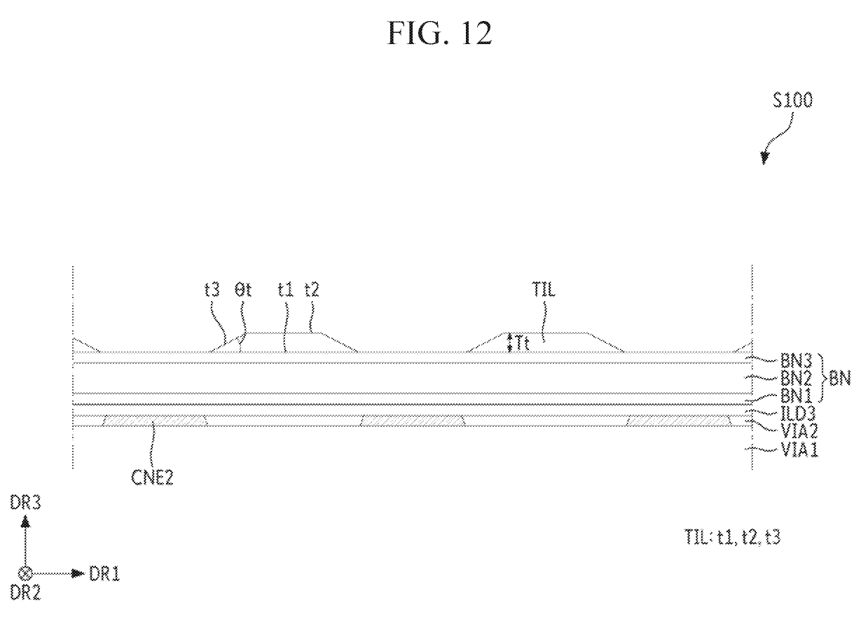

FIGS. 11 and 12 are cross-sectional views illustrating step S100 of FIG. 10.

Referring to FIGS. 11 and 12, the step S100 of forming a temporary insulating layer of a forward tapered shape on a bank structure will be described.

First, a plurality of second connection electrodes CNE2 are formed on a first via layer VIA1, and a second via layer VIA2, a third insulating layer ILD3, and a bank structure BN are entirely formed. In the present process, the bank structure BN may include a first bank layer BN1, a second bank layer BN2, and a third bank layer BN3, which are sequentially stacked.

In the present process, the second bank layer BN2 and the third bank layer BN3 may include their respective materials different from each other. As an example, the third bank layer BN3 may include a material having an etching resistance greater than an etching resistance of the second bank layer BN2. A redundant description will be omitted.

Although not illustrated in the drawing, the thin film transistor layer TFTL including the first via layer VIA1 and the second via layer VIA2 may be positioned on the substrate SUB, and a detailed structure of the thin film transistor layer TFTL is the same as illustrated in FIG. 5.

Subsequently, a temporary insulating layer TIL is formed on the bank structure BN. The temporary insulating layer TIL may be entirely formed on the third bank layer BN3.

The temporary insulating layer TIL may include an inorganic insulating material. For example, the temporary insulating layer TIL may include at least one of silicon nitride, silicon oxide, or silicon oxynitride.

Next, a photoresist PR1 is formed on the temporary insulating layer TIL, and a first etching process is performed. For example, the first etching process may be performed by a dry etching process.

For example, the dry etching process may be formed through a reactive ion etching (RIE) process using reactive gases such as CHF3, CH3F, CH2F2, CHF6, CF4, C2F6 and C3F6 and sputtering gases such as Ar and O₂/Ar. In this case, an inductively coupled plasma (ICP) source or a capacitively coupled plasma (CCP) source may be used as a plasma source.

The photoresist PR1 may be formed by a photo pattern process, and the photoresist PR1 may be formed in plural. In the present process, a portion of the temporary insulating layer TIL, which does not overlap the photoresist PR1, may be removed.

The temporary insulating layer TIL formed through the present process may have a forward tapered shape. In detail, through the present process, the temporary insulating layer TIL may include a lower surface t1 directed toward the bank structure BN, an upper surface t2 facing the lower surface t1, and a side t3 connecting the lower surface t1 to the upper surface t2.

In an embodiment, a width of the upper surface t2 of the temporary insulating layer TIL in the first direction DR1 may be less than a width of the lower surfacet1 of the temporary insulating layer TIL. In some aspects, an inclined angle θt formed by the lower surface t1 and the side t3 of the temporary insulating layer TIL may be an acute angle. For example, the inclined angle θt may be 10° or more and 50° or less.

For example, a thickness Tt of the temporary insulating layer TIL may have a value of 1000 Ω or more and 4000 Ω or less.

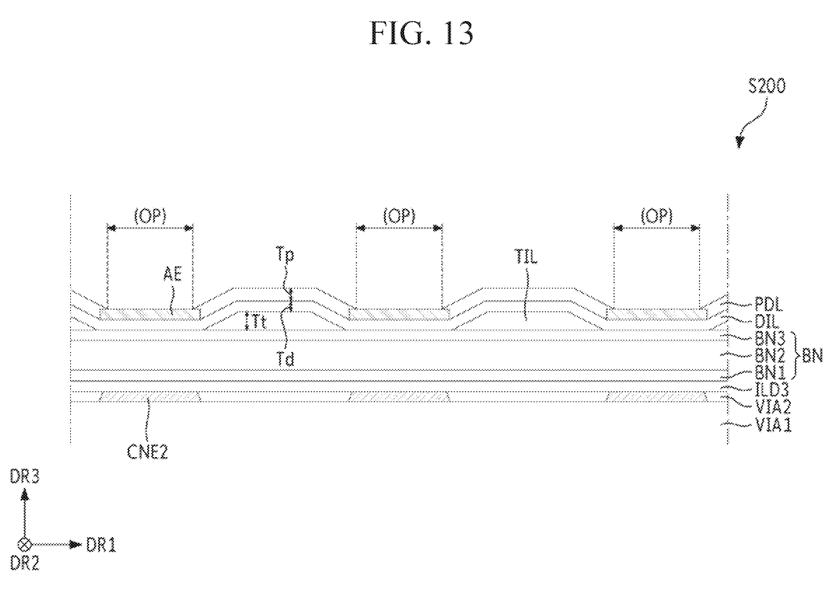

FIGS. 13 - 16 are cross-sectional views illustrating step S200 of FIG. 10.

Referring to FIGS. 13- 16, the step S200 of forming an element insulating layer including a flat portion and an inclined portion will be described.

First, the element insulating layer DIL is formed on the temporary insulating layer TIL and the bank structure BN. The element insulating layer DIL may be covered with a uniform thickness along a profile of a lower structure. The range of the uniform thickness may have a value of 10% or less of a process error. Accordingly, the element insulating layer DIL may be covered along a step difference formed between the temporary insulating layer TIL and the third bank layer BN3.

The element insulating layer DIL includes at least one of the inorganic materials described herein and may be formed through a film forming process. The element insulating layer DIL may entirely cover the temporary insulating layer TIL and the bank structure BN.

In the present process, a thickness Td of the element insulating layer DIL may have a value greater than the thickness Tt of the temporary insulating layer TIL. In an example in which the thickness Tt of the temporary insulating layer TIL has a value of 1000 Ω, the thickness Td of the element insulating layer DIL may have a value greater than 1000 Ω.

In the present process, the element insulating layer DIL and the temporary insulating layer TIL may include the same material, or may include different materials. However, a film density of the element insulating layer DIL may be greater than a film density of the temporary insulating layer TIL.

Next, an anode electrode AE is formed. The anode electrode includes at least one of the above-described metal materials and may be formed through a deposition process and a pattern process. In the present process, a plurality of anode electrodes AE may be formed, and the respective anode electrodes AE may be spaced apart from each other.

Subsequently, a pixel defining layer PDL is formed on the anode electrode AE and the element insulating layer DIL. The pixel defining layer PDL may be covered with a uniform thickness along the profile of the lower structure. The range of the uniform thickness may have a value of 10% or less of a process error. The pixel defining layer PDL includes at least one of the inorganic materials described herein and may be formed through a film forming process and a patterning process.

The pixel defining layer PDL may be patterned to include the light emitting opening OP, and the anode electrode AE may be exposed at a portion that overlaps the light emitting opening OP. The light emitting opening OP may partition the light emission area EA and the non-light emission area NLA.

In the present process, a thickness Tp of the pixel defining layer PDL may have a value greater than the thickness Tt of the temporary insulating layer TIL. In an example in which the thickness Tt of the temporary insulating layer TIL has a value of 1000 Ω, the thickness Td of the pixel defining layer PDL may have a value greater than 1000 Ω.

In the present process, the pixel defining layer PDL may include the same material as the temporary insulating layer TIL, or may include a material different from a material of the temporary insulating layer TIL. However, a film density of the pixel defining layer PDL may be greater than the film density of the temporary insulating layer TIL.

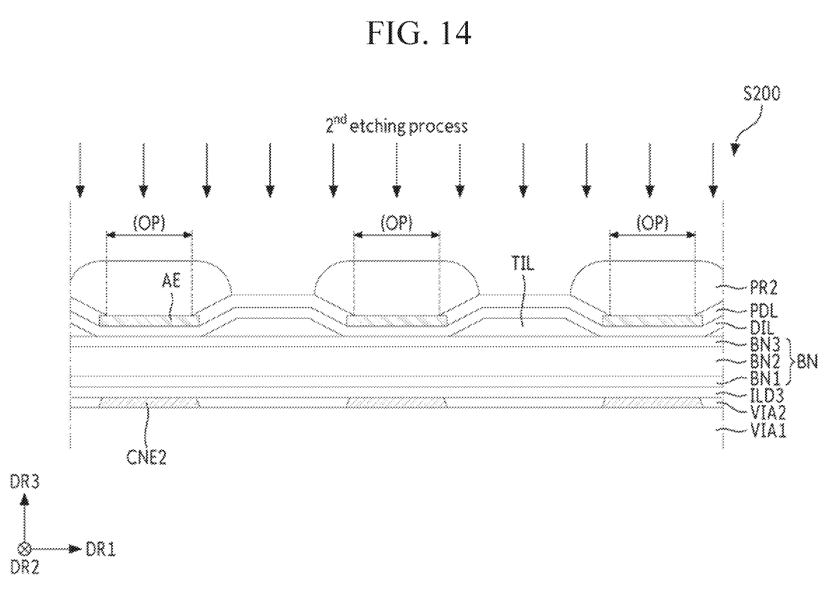

Then, as illustrated in FIG. 14, a photoresist PR2 is formed on the anode electrode AE and the pixel defining layer PDL, and a second etching process is performed. For example, the second etching process may be performed by a dry etching process.

In the present process, the photoresist PR2 may be formed by a photo pattern process and may be formed in plural. The photoresist PR2 may entirely cover the anode electrode AE and may cover a portion of the pixel defining layer PDL.

The second etching process may be performed by being divided into two processes.

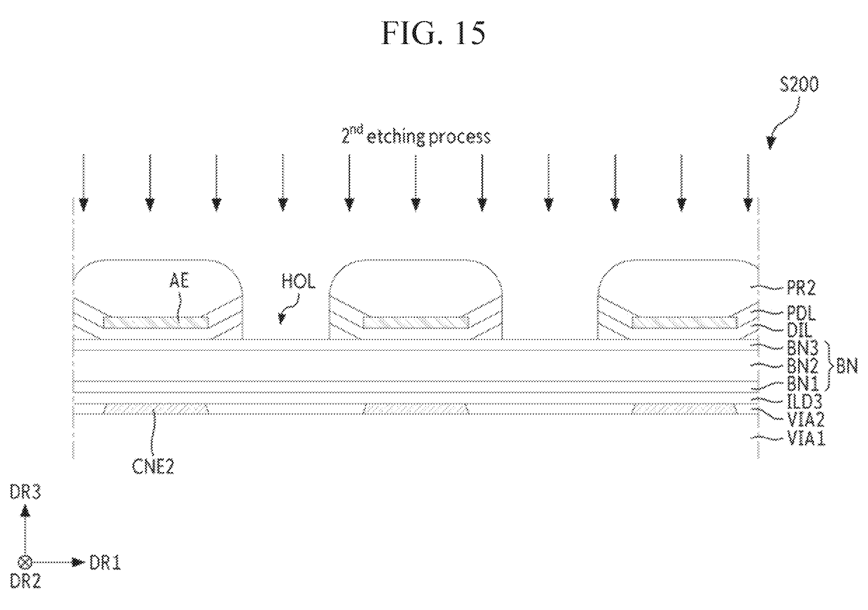

As illustrated in FIG. 15, in the first process, the pixel defining layer PDL, the element insulating layer DIL, and the temporary insulating layer TIL, which do not overlap the photoresist PR2, may be removed simultaneously. Accordingly, a hole HOL may be formed in a portion that does not overlap the photoresist PR2.

In the present process, the bank structure BN overlapping the hole HOL may remain, and a side of the pixel defining layer PDL, a side of the element insulating layer DIL, and a side of the temporary insulating layer TIL, which are directed toward the hole HOL, may be positioned on the same line.

In the following second process, the temporary insulating layer TIL is removed. For example, the present process may be performed by increasing a pressure in a process chamber to form a short mean free path of molecules or atoms in the process chamber.

In the present process, the temporary insulating layer TIL may have etching selectivity different from those of the element insulating layer DIL and the pixel defining layer PDL. Since the film density of the temporary insulating layer TIL of an embodiment includes a value lower than the film density of the element insulating layer DIL and the film density of the pixel defining layer PDL, the temporary insulating layer TIL may be removed through the present process, and the element insulating layer DIL and the pixel defining layer PDL may remain.

In the present process, the film density of the temporary insulating layer TIL may be formed in various ranges depending on process conditions.

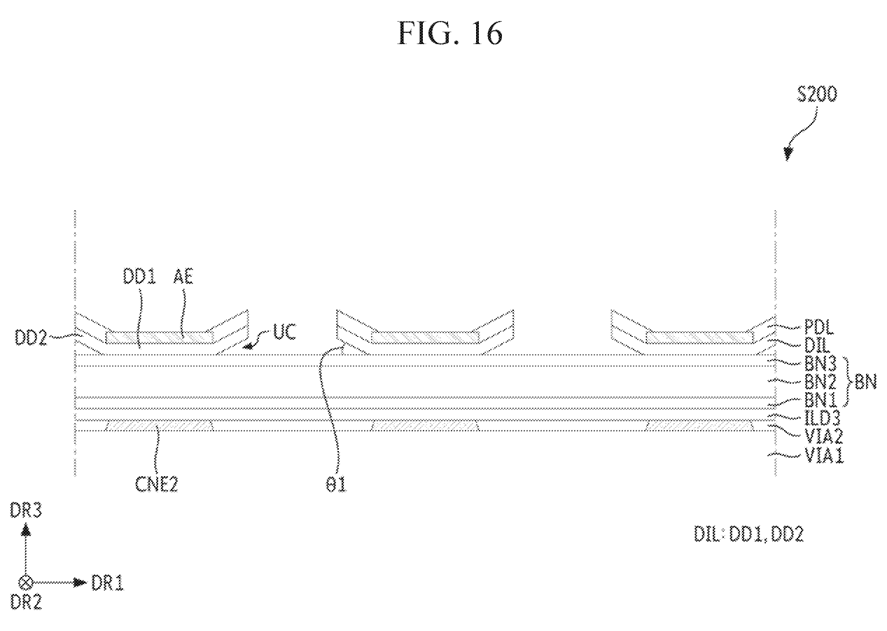

As illustrated in FIG. 16, a space may be formed between the element insulating layer DIL and the third bank layer BN3 through the present process. That is, an undercut UC may be formed between the element insulating layer DIL and the third bank layer BN3. An inclined angle θ1 of the undercut formed in the present process may have a value of 10° to 50°. The undercut UC formed in the present process may be formed by removing the temporary insulating layer TIL including a forward tapered shape.

Through the present process, the element insulating layer DIL may include a flat portion DD1 that is in contact with the bank structure BN and an inclined portion DD2 spaced apart from the bank structure BN. The inclined portion DD2 may be a portion that overlaps the undercut UC. The inclined portion DD2 formed in the present process may be formed as the temporary insulating layer TIL including a forward tapered shape is removed.

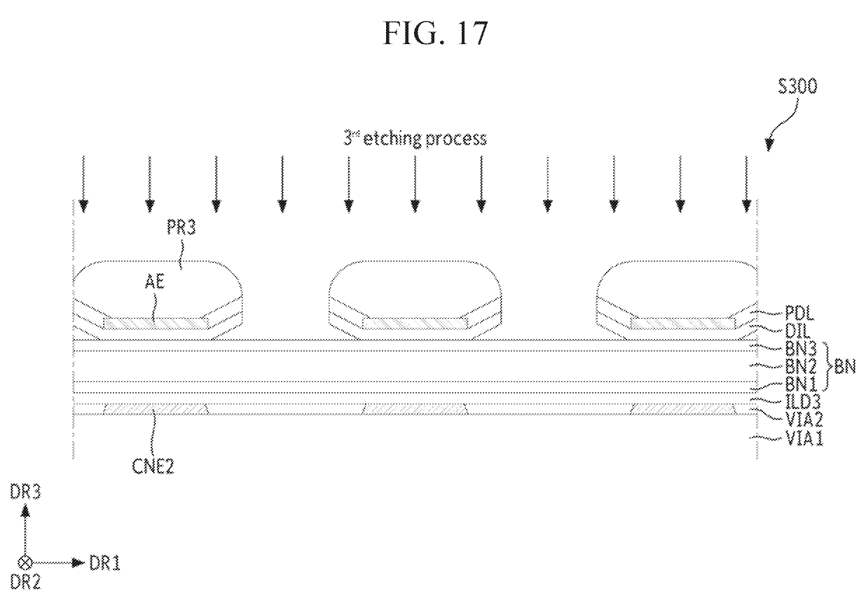

FIGS. 17 - 19 are cross-sectional views illustrating step S300 of FIG. 10.

Referring to FIGS. 17 - 19, the step S300 of forming a tip of the bank structure will be described.

First, a photoresist PR3 is formed on the anode electrode AE and the pixel defining layer PDL, and then a third etching process is performed. For example, the third etching process may alternately perform a dry etching process and a wet etching process. Since the dry etching process has been described herein, its redundant description will be omitted.

For example, the wet etching process may be performed using a liquid chemical solution such as a diluted hydrofluoric acid solution, a nitric acid solution, a tetramethyl ammonium hydroxide solution, and a potassium hydroxide solution.

In the present process, the photoresist PR3 may be formed through a photo pattern process.

The dry etching process is performed as the first process to simultaneously remove the second bank layer BN2 and the third bank layer BN3, which do not overlap the photoresist PR3.

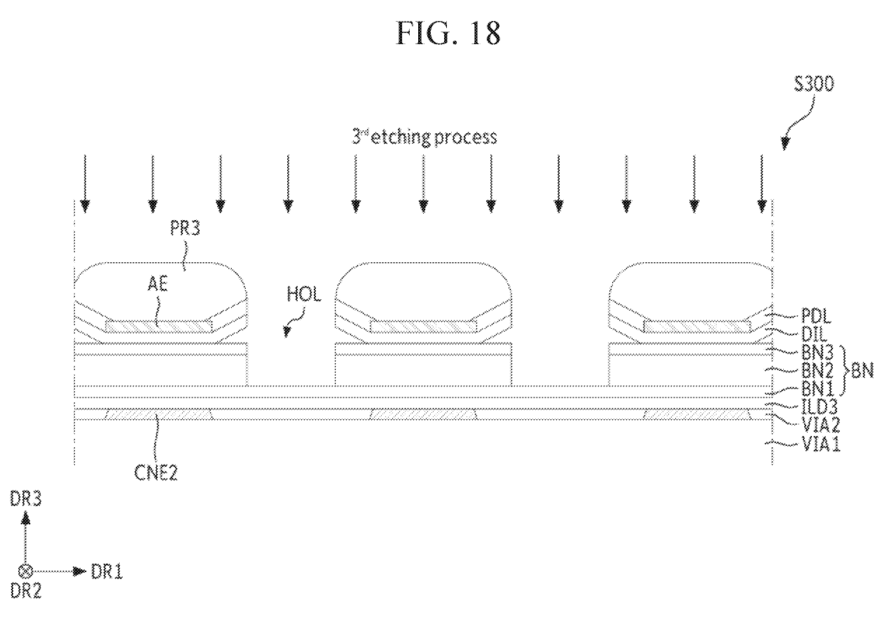

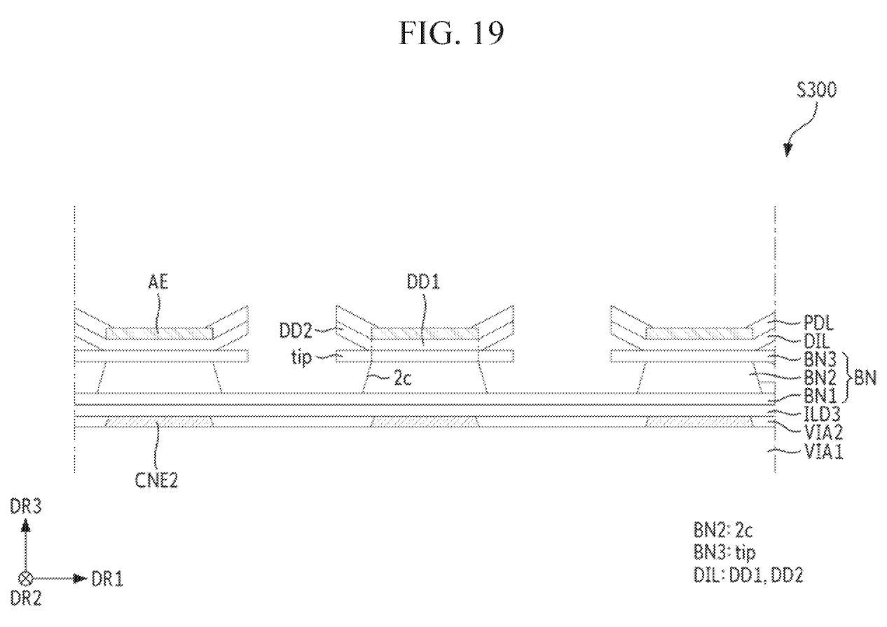

As illustrated in FIG. 18, through the present process, a side of the second bank layer BN2 and a side of the third bank layer BN3, which are directed toward the hole HOL, may be positioned on the same line.

As the second process, the wet etching process is performed to form a tip of the third bank layer BN3. In the present process, the second bank layer BN2 and the third bank layer BN3, which include their respective metal materials different from each other, may have different etching selectivities. In detail, in the same etching process, the third bank layer BN3 may have higher etching resistance than the second bank layer BN2. In other words, in the same etching process, the second bank layer BN2 may include a material having a higher etching rate than the third bank layer BN3.

Through the present process, the third bank layer BN3 may include a tip more protruded in the first direction DR1 than the side 2c of the second bank layer BN2. The inclined portion DD2 of the element insulating layer DIL may overlap the tip of the third bank layer BN3 in the third direction DR3, and a space may be formed between the inclined portion DD2 of the element insulating layer DIL and the tip of the third bank layer BN3.

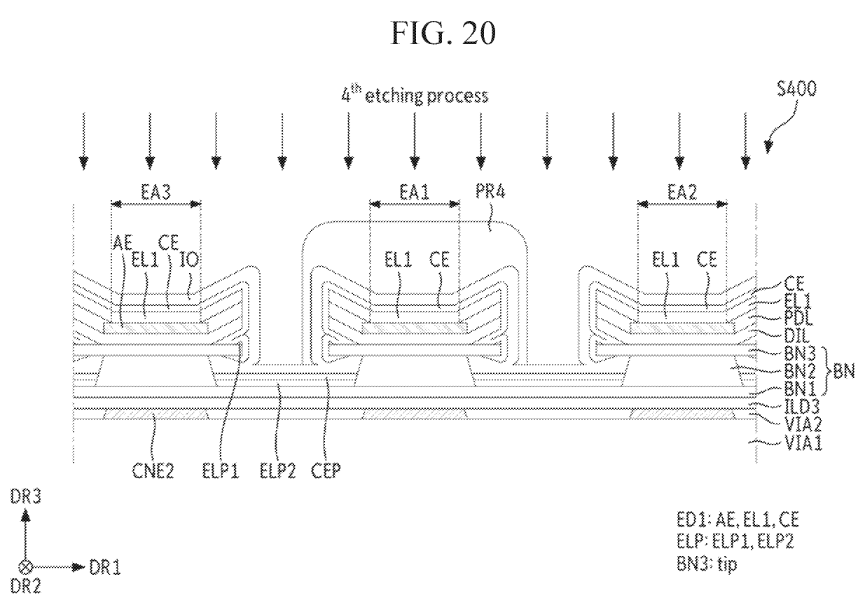

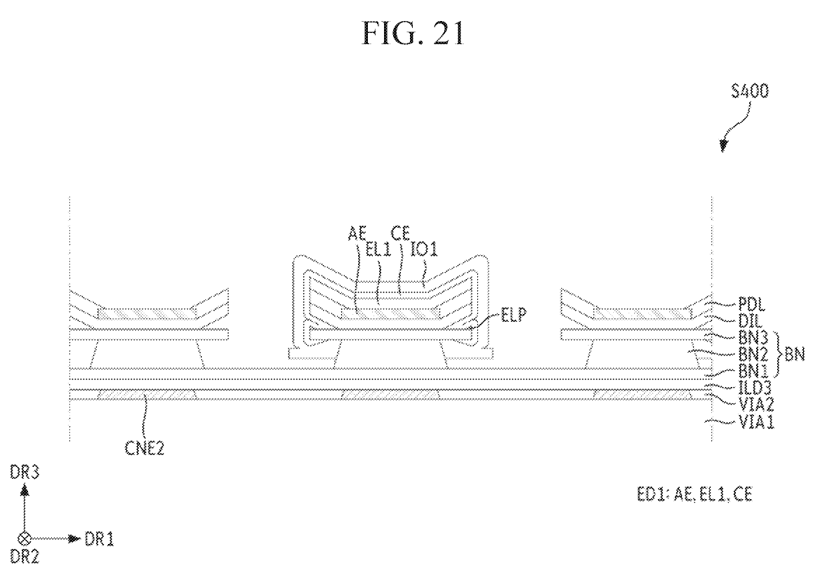

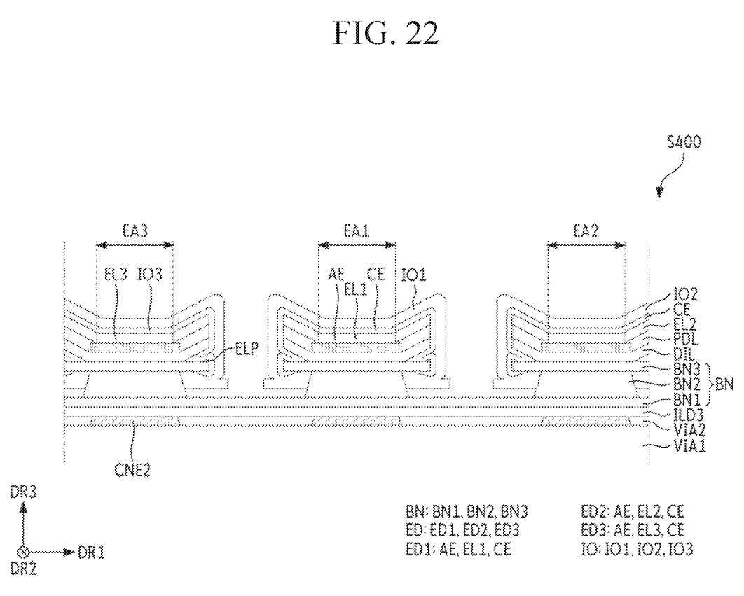

FIGS. 20 - 22 are cross-sectional views illustrating step S400 of FIG. 10.

Referring to FIGS. 20 -22, the step S400 of forming a light emitting element and an element inorganic layer on a bank structure will be described.

First, the first light emitting layer EL1 and the cathode electrode CE are deposited on the anode electrode AE to form the first light emitting element ED1.

In the present process, the process of forming the first light emitting layer EL1 may be performed through a thermal deposition process. In the present process, the process of forming the first light emitting layer EL1 may be performed through a deposition process without using a separate fine metal mask.

For example, the process of forming the first light emitting layer EL1 may be performed by being inclined at an angle of 50° or more from the upper surface of the anode electrode AE. That is, a deposition angle of the process of forming the first light emitting layer EL1 may have a value of 50° or more.

Accordingly, the material for forming the first light emitting layer EL1 may be not only formed on the anode electrode AE overlapping the first light emission area EA1, but also positioned on the anode electrode AE positioned at a portion overlapping the second light emission area EA2 and the third light emission area EA3. The first light emitting layers EL1 positioned at portions overlapping the first to third light emission areas EA1, EA2 and EA3 may be spaced apart from one another.

In some aspects, the material for forming the first light emitting layer EL1 may be also formed on the tip of the third bank layer BN3. The material for forming the first light emitting layer EL1 formed on the tip of the third bank layer BN3 may be referred to as a first organic pattern ELP1 or an organic pattern ELP.

The material for forming the first light emitting layer EL1 may be also formed on the first bank layer BN1. The material for forming the first light emitting layer EL1 formed on the first bank layer BN1 may be referred to as a second organic pattern ELP2 or an organic pattern ELP.

In the present process, the material for forming the first light emitting layer EL1 positioned on the anode electrode AE and the first organic pattern ELP1 and the second organic pattern ELP2 may be spaced apart from each other.

In the present process, a process of forming a cathode electrode CE may be performed through a sputtering process. In the present process, the process of forming the cathode electrode CE may be formed by performing a deposition process without using a separate fine metal mask.

The process of forming the cathode electrode CE may have step coverage characteristics higher than those of the process of forming the first light emitting layer EL1. Accordingly, the cathode electrode CE may entirely cover the first light emitting layer EL1. In some aspects, the cathode electrode CE may cover the pixel defining layer PDL, the element insulating layer DIL, and the tip of the third bank layer BN3. The redundant description will be omitted.

In the present process, the material for forming the cathode electrode CE may be not only formed on the first light emitting layer EL1 overlapping the first light emission area EA1, but also positioned on the first light emitting layer EL1 positioned at a portion overlapping the second light emission area EA2 and the third light emission area EA3. The cathode electrodes CE positioned at portions overlapping the first to third light emission areas EA1, EA2 and EA3 may be spaced apart from one another.

In some aspects, the material for forming the cathode electrode CE may be not only formed on the first light emitting layer EL1, but also formed on the organic pattern ELP. The material for forming the cathode electrode CE positioned on the first light emitting layer EL1 may be integrally formed with the cathode electrode CE positioned on the first organic pattern ELP1.

However, the material for forming the cathode electrode CE positioned on the first light emitting layer EL1 and the material for forming the cathode electrode CE positioned on the second organic pattern ELP2 may be spaced apart from each other. The material for forming the cathode electrode CE formed on the second organic pattern ELP2 may be referred to as an electrode pattern CEP.

The element inorganic layer IO may entirely cover the cathode electrode CE and the electrode pattern CEP. The process of forming the element inorganic layer IO may be formed through a film forming process (e.g., a deposition process) of forming at least one of the inorganic materials described herein.

Next, a photoresist PR4 is formed at a portion overlapping the first light emission area EA1 and a peripheral portion of the first light emission area EA1, and a fourth etching process is performed using the photoresist PR4 as a mask.

In the present process, the material for forming the first light emitting layer EL1, the material for forming the cathode electrode CE, and the material for forming the element inorganic layer IO, which do not overlap the photoresist PR4, may be removed simultaneously. Accordingly, the anode electrode AE that does not overlap the photoresist PR4 may be exposed again.

In the present process, the first organic pattern ELP1 overlapping the photoresist PR4 may remain, and the first organic pattern ELP1 may be referred to as an organic pattern ELP. Both the second organic pattern ELP2 and the electrode pattern CEP may be removed.

In the present process, the element inorganic layer IO may be formed as the first element inorganic layer IO1, and the first element inorganic layer IO1 may be spaced apart from the first bank layer BN1 in the third direction DR3. A gap space between the first element inorganic layer IO1 and the first bank layer BN1 may be formed by removing the second organic pattern ELP2 and the electrode pattern CEP.

As a result, the first light emitting element ED1, the organic pattern ELP, and the first element inorganic layer IO1, which are positioned at a portion overlapping the first light emission area EA1, may be formed.

Subsequently, the above-described process is repeated such that the second light emitting layer EL2, the cathode electrode CE, and the element inorganic layer IO are formed on the anode electrode AE overlapping the second light emission area EA2. Through the present process, the second light emitting element ED2, the organic pattern ELP, and the second element inorganic layer IO2, which overlap the second light emission area EA2, may be formed.

In some aspects, the above-described process is repeated again such that the third light emitting layer EL3, the cathode electrode CE, and the element inorganic layer IO are formed on the anode electrode AE overlapping the third light emission area EA3. Through the present process, the third light emitting element ED3, the organic pattern ELP, and the third element inorganic layer IO3, which overlap the third light emission area EA3, may be formed.

As a result, the display element layer EML illustrated in FIG. 5 may be formed. A redundant description will be omitted.

In the display device 10 according to an embodiment, as the third bank layer BN3 includes a tip, the first light emitting layer EL1, the second light emitting layer EL2, and the third light emitting layer EL3, which are spaced apart from one another, may be formed at portions overlapping the first to third light emission areas EA1, EA2 and EA3 without a separate fine metal mask.

In some aspects, in the display device 10 according to an embodiment, as the third bank layer BN3 includes a tip, the cathode electrodes CE spaced apart from one another may be formed at portions overlapping the first to third light emission areas EA1, EA2 and EA3 without a separate fine metal mask. As a result, the display device 10 according to an embodiment may have easiness in fabrication.

In some aspects, as the display device 10 according to an embodiment includes the light emitting element ED on the bank structure BN, the plurality of light emitting elements ED may be efficiently arranged within a narrow interval. As a result, the display device 10 according to an embodiment may be applied to an electronic device of high resolution.

In the display device 10 of an embodiment, a portion of the element insulating layer DIL is formed to have a tapered angle of 10° to 50° with respect to the tip of the third bank layer BN3, such that a contact area between the cathode electrode CE and the bank structure BN may be increased through the space formed between the tip of the third bank layer BN3 and the inclined portion DD2 of the element insulating layer DIL. As a result, the display device 10 according to an embodiment may resolve reliability defects such as a power supply failure or a luminance failure.

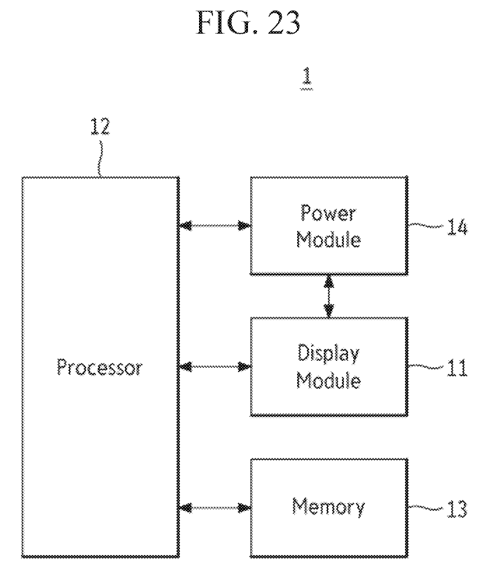

FIG. 23 is a block diagram illustrating an electronic device according to an embodiment.

Referring to FIG. 23 in addition to FIGS. 1 - 22, the display device 10 according to an embodiment may be applied to various electronic devices 1. The electronic device 1 according to an embodiment includes the display device 10 described herein, and the electronic device 1 may further include modules or devices having other additional functions in addition to the display device 10.

An electronic device 1 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

Data information supportive of an operation of the processor 12 or the display module 11 may be stored in the memory 13. In an example in which the processor 12 executes an application stored in the memory 13, an image data signal and/or an input control signal is transmitted to the display module 11, and the display module 11 may process the received signal and output image information through a display screen.

The power module 14 may include a power supply module such as a power adapter or a battery device, and a power conversion module that converts a power source supplied by the power supply module to generate a power source for the operation of the electronic device 1.

At least one of the respective components of the above-described electronic device 1 may be included in the display device according to the above-described embodiments. In some aspects, some of the individual modules functionally included in one module may be included in the display device, and others thereof may be provided separately from the display device. For example, the display device includes the display module 11, and the processor 12, the memory 13 and the power module 14 may be provided as other devices in the electronic device 1 not the display device.

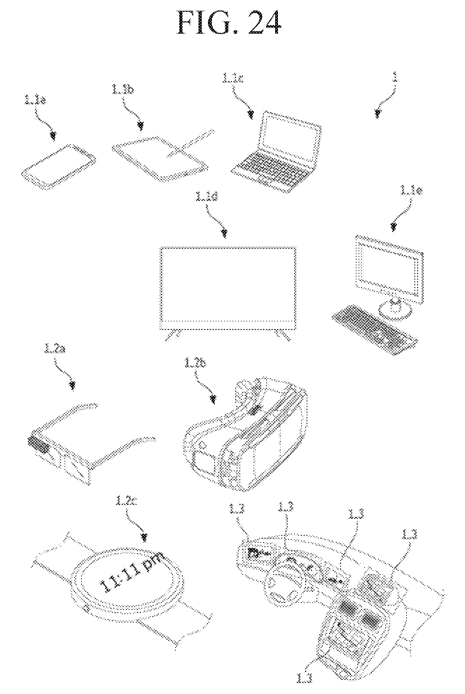

FIG. 24 illustrates schematic views of electronic devices according to various embodiments.

Referring to FIG. 24, various electronic devices 1 to which the display device 10 according to the embodiments are applied may include not only electronic devices for image display, such as a smart phone 1_1a, a tablet PC 1_1b, a laptop 1_1c, a TV 1_1d, and a desk monitor 1_1e, but also wearable electronic devices including display modules such as smart glasses 1_2a, a head mounted display 1_2b, and a smart watch 1_2c, and a vehicle electronic device 1_3 including display modules such as a vehicle dashboard, a center fascia, a center information display (CID) arranged on the dashboard, and a room mirror display.

Embodiments of the disclosure should not be construed as being limited to the embodiments set forth herein. Rather, the example embodiments are provided such that this disclosure will be thorough and complete and will fully convey the concept of the invention to those skilled in the art.

While the invention has been particularly illustrated and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate comprising a light emission area and a non-light emission area;
a bank structure positioned on the light emission area of the substrate and having an overhang structure;
an anode electrode positioned on the bank structure; and
an element insulating layer positioned between the bank structure and the anode electrode,
wherein:
the element insulating layer comprises a flat portion overlapping the light emission area and an inclined portion overlapping with the non-light emission area and connected to respective sides of the flat portion,
the flat portion is in contact with the bank structure,
the inclined portion is spaced apart from the bank structure, and
an inclined angle formed by the bank structure and the inclined portion of the element insulating layer is an acute angle.

2. The display device of claim 1, wherein the inclined angle formed by the bank structure and the inclined portion of the element insulating layer ranges from 10° to 50°.

3. The display device of claim 2, wherein:
the bank structure comprises:
a first bank layer;
a second bank layer positioned on the first bank layer; and
a third bank layer comprising a tip more protruded toward the non-light emission area than a side of the second bank layer,
the flat portion is positioned in contact with the third bank layer,
the inclined portion is spaced apart from the third bank layer, and
the inclined portion overlaps the tip of the third bank layer.

4. The display device of claim 3, wherein:
the inclined portion comprises a first surface directed toward the third bank layer, and
a spaced distance between the third bank layer and the first surface increases in a direction away from a contact point at which the third bank layer is in contact with the first surface.

5. The display device of claim 4, wherein the spaced distance between the third bank layer and the first surface ranges from 1000 Ω to 4000 Ω.

6. The display device of claim 3, further comprising:
a pixel defining layer covering an edge of the anode electrode and defining a light emitting opening; and
a light emitting layer positioned on the anode electrode,
wherein the light emitting layer comprises:
a light emitting flat portion that is in contact with the anode electrode at a portion overlapping the light emitting opening, and
a light emitting inclined portion connected to respective sides of the light emitting flat portion and non-overlapping with the light emitting opening.

7. The display device of claim 6, wherein:
the light emitting inclined portion further comprises a first surface directed toward the anode electrode, and
an inclined angle formed by the anode electrode and the first surface is an acute angle.

8. The display device of claim 6, further comprising a cathode electrode positioned on the light emitting layer,
wherein:
the third bank layer further comprises an upper surface directed toward the element insulating layer, and
the upper surface of the third bank layer comprises a first portion that is in contact with the flat portion of the element insulating layer and a second portion that is in contact with the cathode electrode.

9. The display device of claim 6, further comprising an organic pattern positioned between the tip of the third bank layer and the inclined portion of the element insulating layer and spaced apart from the light emitting layer, wherein the organic pattern comprises the same material as the light emitting layer.

10. A method for fabricating a display device, the method comprising:
forming a temporary insulating layer of a forward tapered shape on a bank structure;
forming an element insulating layer comprising a flat portion and an inclined portion;
forming a tip of the bank structure; and
forming a light emitting element and an element inorganic layer on the bank structure.

11. The method of claim 10, wherein:
the temporary insulating layer comprises a first surface directed toward the bank structure and a side connected to the first surface, and
an inclined angle formed by the first surface and the side ranges from 10° to 50°.

12. The method of claim 11, wherein:
the element insulating layer and the temporary insulating layer comprise an inorganic insulating material, and
the element insulating layer has a film density different from a film density of the temporary insulating layer.

13. The method of claim 12, further comprising:
forming a pixel defining layer positioned on the inclined portion of the element insulating layer, the pixel defining layer comprising an inorganic insulating material,
wherein a film density of the element insulating layer and a film density of the pixel defining layer are each higher than a film density of the temporary insulating layer.

14. The method of claim 13, wherein a thickness of the temporary insulating layer is less than each of a thickness of the element insulating layer and a thickness of the pixel defining layer.

15. The method of claim 10, wherein:
the forming the tip of the bank structure comprises forming the bank structure that comprises a first bank layer, a second bank layer, and a third bank layer,
the second bank layer comprises aluminum,
the third bank layer comprises titanium, and
the third bank layer comprises a tip more protruded than a side of the second bank layer.

16. The method of claim 10, wherein:
the forming the light emitting element and the element inorganic layer on the bank structure comprises forming a light emitting layer and a cathode electrode by a photo pattern process without a separate fine metal mask,
wherein the light emitting element comprises the light emitting layer and the cathode electrode.

17. An electronic device comprising:
at least one display device comprising a substrate comprising a light emission area and a non-light emission area; and
at least one of a display module, a processor, a memory, or a power module, which is connected to the at least one display device,
wherein the at least one display device comprises:
a bank structure positioned on the light emission area of the substrate and having an overhang structure;
an anode electrode positioned on the bank structure; and
an element insulating layer positioned between the bank structure and the anode electrode,
wherein:
the element insulating layer comprises a flat portion overlapping the light emission area and an inclined portion overlapping with the non-light emission area and connected to respective sides of the flat portion,
the flat portion is in contact with the bank structure,
the inclined portion is spaced apart from the bank structure, and
an inclined angle formed by the bank structure and the inclined portion of the element insulating layer is an acute angle.

18. The electronic device of claim 17, wherein the inclined angle formed by the bank structure and the inclined portion of the element insulating layer ranges from 10° to 50°.

19. The electronic device of claim 18, wherein:
the bank structure comprises:
a first bank layer;
a second bank layer positioned on the first bank layer; and
a third bank layer comprising a tip more protruded toward the non-light emission area than a side of the second bank layer,
the flat portion is positioned in contact with the third bank layer,
the inclined portion is spaced apart from the third bank layer, and
the inclined portion overlaps the tip of the third bank layer.

20. The electronic device of claim 19, wherein:
the inclined portion comprises a first surface directed toward the third bank layer,
a spaced distance between the third bank layer and the first surface increases in a direction away from a contact point at which the third bank layer is in contact with the first surface, and
the spaced distance between the third bank layer and the first surface ranges from 1000 Ω to 4000 Ω.
